(19) United States
(12) Patent Application Publication
(10) Pub. No.: US 2026/0293648 A1
(43) Pub. Date: Sep. 24, 2026

(54) SEMICONDUCTOR INTEGRATED CIRCUIT DEVICE

(71) Applicant: Socionext Inc., Kanagawa (JP)

(72) Inventor: Takenobu KAWAI, Yokohama-shi (JP)

(21) Appl. No.: 19/689,981

(22) Filed: May 27, 2026

Related U.S. Application Data
(63) Continuation of application No. PCT/JP2024/033982, filed on Sep. 24, 2024.

(30) Foreign Application Priority Data
Nov. 30, 2023 (JP) 2023-202450

(51) Int. Cl. H10W 20/43; H10D 62/10; H10D 84/83; H10W 20/41; H10W 20/42

(52) U.S. Cl. CPC H10W 20/43; H10D 62/126; H10D 84/832; H10W 20/422; H10W 20/427; H10D 62/121

(57) ABSTRACT

A standard cell includes a power supply line formed in a back wiring layer, and a via formed in an overlap region between a region of an active region serving as the source of a transistor and the power supply line, the via connecting the source in the active region and the power supply line. A nanosheet has a surface on one side in a Y direction, which is exposed from a gate line. A nanosheet has a surface on the other side in the Y direction, which is exposed from a gate line. The via is disposed at a center portion of the active region in the Y direction in plan view.

### CROSS-REFERENCE TO RELATED APPLICATIONS

This is a continuation of International Application No. PCT/JP2024/33982 filed on Sep. 24, 2024, which claims priority to Japanese Patent Application No. 2023-202450 filed on Nov. 30, 2023. The entire disclosures of these applications are incorporated by reference herein.

### BACKGROUND

The present disclosure relates to a semiconductor integrated circuit device including a standard cell (hereinafter also simply referred to as a cell as appropriate) including a forksheet transistor.

Standard cell method is known as a method of forming a semiconductor integrated circuit on a semiconductor substrate. The standard cell method is a method of designing an LSI chip by preparing in advance, as standard cells, basic units (e.g., an inverter, a latch, a flip-flop, or a full adder) with specific logic functions, arranging the standard cells on a semiconductor substrate, and connecting the standard cells by lines.

Further, the gate length of a transistor which is a basic component of an LSI has been reduced (scaling) to improve integration degree, reduce the operating voltage, and improve the operating speed. However, an off-current due to excessive scaling and a significant increase in power consumption due to the off-current have been concerned in recent years. To address this concern, studies have been actively conducted for a transistor having a three-dimensional structure in which a configuration of a transistor is changed from a traditional planar type to a three-dimensional type. One of the transistors having the three-dimensional structure is a nanosheet FET.

United States Patent Application Publication No. 2022/0246644 discloses a standard cell using a forksheet transistor having a gate electrode in a fork shape among nanosheet FETs for reducing the area of a semiconductor integrated circuit device. United States Patent Application Publication No. 2022/0246644 discloses the structure of a terminal cell among the standard cells using the forksheet transistor.

### SUMMARY

Meanwhile, United States Patent Application Publication No. 2022/0375761 discloses a standard cell in which for reducing the area of a semiconductor integrated circuit device, a back line is provided on a back surface immediately below a transistor and the source and drain of the transistor are connected thereto.

However, specific studies have not been conducted yet on the standard cell using the forksheet transistor and the back line.

An object of the present disclosure is to provide the layout of a semiconductor integrated circuit device including a standard cell using a forksheet transistor and a back line.

A first aspect of the present disclosure is directed to a semiconductor integrated circuit device including a plurality of standard cells including a first standard cell, the first standard cell includes a first active region forming a channel, a source, and a drain of a first transistor of a first conductivity type and having a first nanosheet extending in a first direction as the channel, a second active region forming a channel, a source, and a drain of a second transistor of a second conductivity type which is a conductivity type different from the first conductivity type and having a second nanosheet extending in the first direction as the channel, a first gate line extending in a second direction perpendicular to the first direction and surrounding an outer periphery of the first nanosheet in the second direction and a third direction perpendicular to the first direction and the second direction, a second gate line extending in the second direction and surrounding an outer periphery of the first nanosheet in the second direction and the third direction, a first power supply line formed on a back surface side of the first transistor and extending in the first direction, a second power supply line formed on a back surface side of the second transistor and extending in the first direction, and a first via formed in an overlap region between a region of the first active region serving as the source of the first transistor and the first power supply line, the first via connecting the source in the first active region and the first power supply line, the second nanosheet is disposed on a first side of the first nanosheet, which is one side in the second direction, a surface of the first nanosheet on the first side is exposed from the first gate line, a surface of the second nanosheet on a second side which is the other side in the second direction is exposed from the second gate line, and the first via is disposed at a center portion of the first active region in the second direction in plan view.

According to the present disclosure, in the first and second nanosheets, the surfaces facing each other in the second direction are exposed from the first and second gate lines, respectively. This makes it possible to reduce a distance in the second direction between the first and second active regions in the first standard cell. The first via connecting the first power supply line and the portion of the first active region serving as the source of the first transistor is disposed at the center portion of the first active region in the second direction in plan view. Thus, the distances from the first via to both the ends of the portion of the first active region, which serves as the source of the first transistor, in the second direction are equal to each other, and therefore, the current flowing through the first transistor is equalized on both sides in the second direction. Thus, the area of the semiconductor integrated circuit device can be reduced, and the speed of the semiconductor integrated circuit device can be increased.

A second aspect of the present disclosure is directed to a semiconductor integrated circuit device including a plurality of standard cells including a first standard cell, the first standard cell includes a first active region forming a channel, a source, and a drain of a first transistor of a first conductivity type and having a first nanosheet extending in a first direction as the channel, a second active region forming a channel, a source, and a drain of a second transistor of a second conductivity type which is a conductivity type different from the first conductivity type and having a second nanosheet extending in the first direction as the channel, a first gate line extending in a second direction perpendicular to the first direction and surrounding an outer periphery of the first nanosheet in the second direction and a third direction perpendicular to the first direction and the second direction, a second gate line extending in the second direction and surrounding an outer periphery of the first nanosheet in the second direction and the third direction, a first power supply line formed on a back surface side of the first transistor and extending in the first direction, a second power supply line formed on a back surface side of the second transistor and extending in the first direction, and a first via formed in an overlap region between a region of the first active region serving as the source of the first transistor and the first power supply line, the first via connecting the source in the first active region and the first power supply line, the second nanosheet is disposed on a first side of the first nanosheet, which is one side in the second direction, a surface of the first nanosheet on the first side is exposed from the first gate line, a surface of the second nanosheet on a second side which is the other side in the second direction is exposed from the second gate line, and the amount of overlap of the first active region on the first side in the second direction with the first via is greater than the amount of overlap of the first power supply line on the first side in the second direction with the first via.

A third aspect of the present disclosure is directed to a semiconductor integrated circuit device including a plurality of standard cells including a first standard cell, the first standard cell includes a first active region forming a channel, a source, and a drain of a first transistor of a first conductivity type and having a first nanosheet extending in a first direction as the channel, a second active region forming a channel, a source, and a drain of a second transistor of a second conductivity type which is a conductivity type different from the first conductivity type and having a second nanosheet extending in the first direction as the channel, a first gate line extending in a second direction perpendicular to the first direction and surrounding an outer periphery of the first nanosheet in the second direction and a third direction perpendicular to the first direction and the second direction, a second gate line extending in the second direction and surrounding an outer periphery of the second nanosheet in the second direction and the third direction, a first power supply line formed on a back surface side of the first transistor and extending in the first direction, a second power supply line formed on a back surface side of the second transistor and extending in the first direction, and a first via formed in an overlap region between a region of the first active region serving as the source of the first transistor and the first power supply line, the first via connecting the source in the first active region and the first power supply line, the second nanosheet is disposed on a first side of the first nanosheet, which is one side in the second direction, a surface of the first nanosheet on a second side which is the other side in the second direction is exposed from the first gate line, a surface of the second nanosheet on the first side is exposed from the second gate line, and the first via is disposed at a center portion of the first active region in the second direction in plan view.

According to the present disclosure, it is possible to reduce the area of the semiconductor integrated circuit device and increase the speed of the semiconductor integrated circuit device.

### BRIEF DESCRIPTION OF THE DRAWINGS

FIG. 1 is a plan view of a layout example of circuit blocks in a semiconductor integrated circuit device according to a first embodiment.

FIG. 2 shows plan views of examples of layout structure of an inverter cell according to the first embodiment.

FIG. 3 shows sectional views of the inverter cell of FIG. 2.

FIG. 4 is a circuit diagram of the inverter cell of FIG. 2.

FIG. 5 shows another configuration example of the semiconductor integrated circuit device according to the first embodiment.

FIG. 6 is a plan view of an example of the layout structure of the inverter cell according to a variation of the first embodiment.

FIG. 7A shows plan views showing an example of the layout structure of a standard cell in a first semiconductor integrated circuit device.

FIG. 7B shows plan views showing an example of the layout structure of the standard cell in the first semiconductor integrated circuit device.

FIG. 8 shows circuit diagrams of the standard cell of FIGS. 7A and 7B.

FIG. 9 is a plan view showing a layout example of circuit blocks in a semiconductor integrated circuit device according to a second embodiment.

FIG. 10 shows plan views showing examples of the layout structure of an inverter cell according to the second embodiment.

FIG. 11A shows plan views showing an example of the layout structure of a standard cell in a second semiconductor integrated circuit device.

FIG. 11B shows plan views showing an example of the layout structure of the standard cell in the second semiconductor integrated circuit device.

### DETAILED DESCRIPTION

Embodiments will be described below with reference to the drawings. The following embodiments assume a semiconductor integrated circuit device including a plurality of standard cells, at least some of which include a forksheet transistor having a gate electrode in a fork shape among nanosheet FETs. The nanosheet FET is an FET using a thin sheet (nanosheet) through which current flows. The nanosheet is made of silicon, for example. In the semiconductor integrated circuit device, some of the nanosheet FETs are forksheet FETs having gate electrodes in a fork shape.

In this specification, “VDD” and “VSS” indicate power supply voltages or power sources themselves. In this specification, expressions indicating that the widths and the like are the same, such as “the same line width”, shall be understood to include manufacturing tolerances.

### First Embodiment

### Configuration of Circuit Block

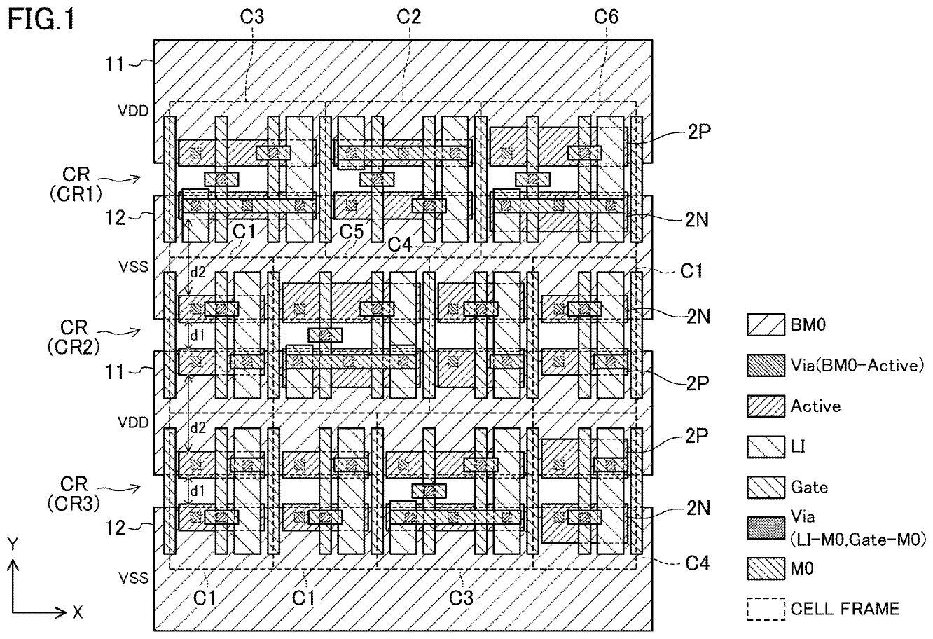

FIG. 1 is a plan view of an example of the layout of circuit blocks in a semiconductor integrated circuit device according to a first embodiment. The block layout of FIG. 1 is formed by disposing standard cells. In the present embodiment, a power supply line is formed in a backside metal 0 (BM0) wiring layer, which is a wiring layer provided on the back surface of a semiconductor chip on which a transistor is formed.

In the following description, the lateral direction of the figure in the plan view of FIG. 1 or the like is an X direction (corresponding to a first direction), the longitudinal direction of the figure is a Y direction (corresponding to a second direction), and a direction perpendicular to a substrate surface is a Z direction (corresponding to a third direction). Further, in the following description, the same reference characters are used to represent the same elements, and description thereof may be omitted.

A dotted line surrounding a cell in the plan view of FIG. 1 or the like indicates a cell frame of the standard cell (outer edge of the standard cell). The standard cell is disposed such that its cell frame contacts a cell frame of an adjacent cell in the X direction or the Y direction.

In the layout of FIG. 1, a plurality of cells arranged in the X direction form a cell row CR (CR1 to CR3). A plurality of cell rows CR (three rows in FIG. 1) are disposed in the Y direction. The plurality of cells include cells having logic functions, such as an inverter, a NAND gate, and a NOR gate. For example, the cell row CR includes inverter cells C1, C4, 2-input NAND cells C2, C5, 2-input NOR cells C3, C6, and the like to be described later.

At each end of each cell in the Y direction in the BM0 wiring layer, a power supply line is formed, and power supply voltages VDD, VSS are supplied to the cell from the outside through the power supply line. The cell rows CR are disposed so as to be alternately reversed in the Y direction. At a boundary between adjacent cell rows CR, the power supply line (power supply line 11 described later) that supplies the power supply voltage VDD is continuous in the X direction, and the power supply line (power supply line 12 described later) that supplies the power supply voltage VSS is continuous in the X direction. That is, in the BM0 wiring layer, the power supply lines extending in the X direction are formed, and the power supply lines that supply the power supply voltage VDD and the power supply lines that supply the power supply voltage VSS are alternately disposed in the Y direction.

Each cell includes an active region 2P forming the channel, source, and drain of a P-type transistor, and an active region 2N forming the channel, source, and drain of an N-type transistor. In the cell row CR, the active regions 2P are arranged in the X direction, and the active regions 2N are arranged in the X direction. In cell rows CR adjacent to each other in the Y direction, the active regions 2P are disposed so as to face each other, and the active regions 2N are disposed so as to face each other. A distance d1 in the Y direction between the active regions 2P, 2N in the cell is smaller than a distance d2 between the active regions 2P (2N) between the cell rows CR.

In the cell row CR1, CR3, the lower ends of the active regions 2P of the cells in the Y direction are arranged in the X direction, and the upper ends of the active regions 2N of the cells in the Y direction are arranged in the X direction, as shown in the figure. In the cell row CR2, the lower ends of the active regions 2N of the cells in the Y direction are arranged in the X direction, and the upper ends of the active regions 2P of the cells in the Y direction are arranged in the X direction, as shown in the figure. That is, in the cell row CR, in each cell, the active regions 2P, 2N are arranged such that end portions thereof on the side where the active regions 2P, 2N face each other are in line in the X direction.

### Configuration of Inverter Cell C1

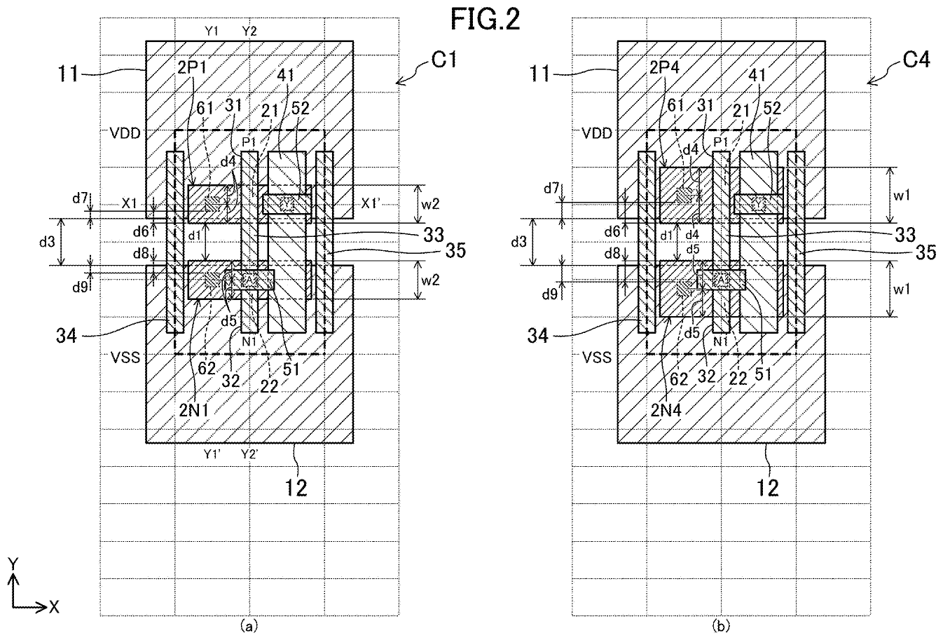

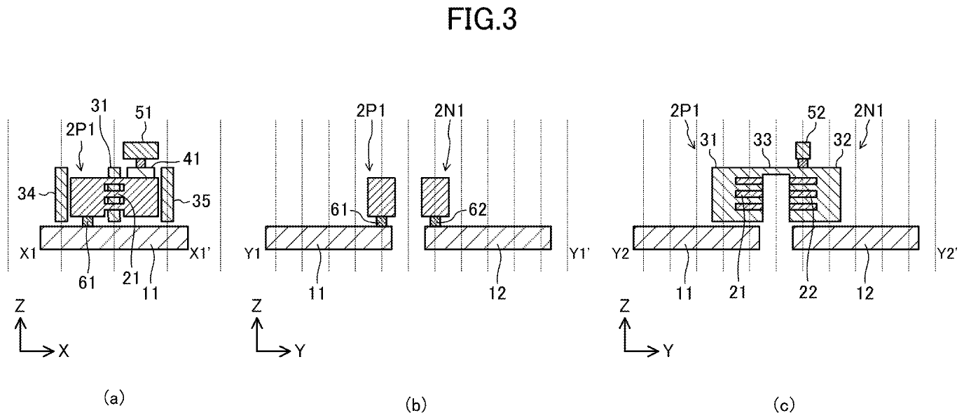

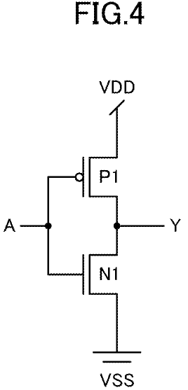

FIG. 2 shows plan views showing an example of layout structures of the inverter cells C1, C4 according to the first embodiment, FIG. 3 shows sectional views showing an example of a layout structure of an inverter cell according to the first embodiment, and FIG. 4 is a circuit diagram of the inverter cell according to the first embodiment. Specifically, in FIG. 2, (a) is a plan view of the inverter cell C1, (b) is a plan view of the inverter cell C4, and in FIG. 3, (a) is a sectional view taken along line X1-X1′ in FIG. 2, (b) is a sectional view taken along line Y1-Y1′ in FIG. 2, and (c) is a sectional view taken along line Y2-Y2′ in FIG. 2.

In the following description, dashed lines running longitudinally and laterally in the plan views of FIG. 2 and the like and dashed lines running longitudinally in the sectional views of FIG. 3 and the like indicate grids used for disposing components at the time of designing. The grids are disposed at equal intervals in the X direction, and are disposed at equal intervals in the Y direction. The intervals of the grids in the X direction and those in the Y direction may be the same as each other or different from each other. The intervals of the grids may be different among layers. Further, each component is not necessarily disposed on the grid.

As shown in FIG. 4, the inverter cell C1 has transistors P1, N1, and forms an inverter circuit having an input A and an output Y.

As shown in FIG. 2, the BM0 wiring layer, which is the wiring layer, is formed on the back surface of the semiconductor chip on which the transistors are formed. The power supply lines 11, 12 are shared with other cells in the cell row CR including the inverter cell C1, and serve as power supply lines extending in the X direction.

The BM0 wiring layer includes the power supply lines 11, 12 extending in the X direction at both ends of the cell in the Y direction in the figure. The power supply line 11 supplies the power supply voltage VDD. The power supply line 12 supplies the power supply voltage VSS.

An active region forming the channel, source, and drain of a P-type transistor is formed in a P-type transistor region on an N-type well (NWell). Specifically, an active region 2P1 is formed in the P-type transistor region. The active region 2P1 overlaps the power supply line 11 in plan view.

In the P-type transistor region, a P-type transistor P1 is formed. The transistor P1 has, as a channel, a nanosheet 21 which has a triple-sheet structure overlapping each other in plan view and extends in the X direction. In the active region 2P1, a portion serving as the source of the transistor P1 is connected to the power supply line 11 through a via 61. The via 61 is formed in an overlap region between the power supply line 11 and the active region 2P1 in plan view.

An active region forming the channel, source, and drain of an N-type transistor is formed in an N-type transistor region on a P-type substrate (PSub) (not shown). Specifically, an active region 2N1 is formed in the N-type transistor region. The active region 2N1 overlaps the power supply line 12 in plan view.

In the N-type transistor region, an N-type transistor N1 is formed. The transistor N1 has, as a channel, a nanosheet 22 which has a triple-sheet structure overlapping each other in plan view and extends in the X direction. In the active region 2N1, a portion serving as the source of the transistor N1 is connected to the power supply line 12 through a via 62. The via 62 is formed in an overlap region between the power supply line 12 and the active region 2N1 in plan view.

In the active region, portions serving as the source and the drain on both sides of the nanosheet are formed by epitaxial growth of the nanosheet, for example.

A gate line 31, 32 extending in the Y direction is formed at a cell center portion in the X direction. The nanosheet 21 overlaps the gate line 31 in plan view. The nanosheet 22 overlaps the gate line 32 in plan view. The gate line 31 corresponds to the gate of the transistor P1. The gate line 32 corresponds to the gate of the transistor N1.

As shown in (c) of FIG. 3, the gate line 31 covers the outer periphery of the nanosheet 21 in the Y direction and the Z direction such that part of the outer periphery of the nanosheet 21 is exposed. The gate line 32 covers the outer periphery of the nanosheet 22 in the Y direction and the Z direction such that part of the outer periphery of the nanosheet 22 is exposed. Specifically, the side surface of the nanosheet 21 on the right side in the figure is not covered with the gate line 31. The side surface of the nanosheet 22 on the left side in the figure is not covered with the gate line 32. That is, the side surface of the nanosheet 21 on the right side in the figure is exposed from the gate line 31. The side surface of the nanosheet 22 on the left side in the figure is exposed from the gate line 32. Thus, in FIG. 2, in the nanosheet 21, a lower surface in the Y direction in the figure is exposed from the gate line 31, and an upper surface in the Y direction in the figure is covered with the gate line 31. In the nanosheet 22, an upper surface in the Y direction in the figure is exposed from the gate line 32, and a lower surface in the Y direction in the figure is covered with the gate line 32.

The gate lines 31, 32 are connected through a bridge portion 33 extending in the Y direction.

As shown in FIG. 2, dummy gate lines 34, 35 are formed on the cell frames on both sides in the X direction. The dummy gate line 34 is shared with other cells disposed on the left side in the figure. The dummy gate line 35 is shared with other cells disposed on the right side in the figure.

In a local wiring layer, a local line (LI: local interconnect) 41 extending in the Y direction is formed. The local line 41 is connected to the portion of the active region 2P1 serving as the drain of the transistor P1 and the portion of the active region 2N1 serving as the drain of the transistor N1.

In a M0 wiring layer, which is a metal wiring layer above the local wiring layer, lines 51, 52 extending in the X direction are formed. The line 51 is connected to the gate line 32 through a via. The line 52 is connected to the local line 41 through a via. The line 51 corresponds to the input A, and the line 52 corresponds to the output Y.

As described above, the inverter cell C1 has the P-type transistor P1 and the N-type transistor N1, and forms the inverter circuit having the input A and the output Y.

As shown in (a) of FIG. 2, the active region 2P1, 2N1 in the inverter cell C1 has a width w2 in the Y direction in plan view.

In the inverter cell C1 of FIG. 2, the lower surface of the nanosheet 21 in the Y direction in the figure is exposed from the gate line 31. In the nanosheet 22, an upper surface in the Y direction in the figure is exposed from the gate line 32. That is, the nanosheets 21, 22 have surfaces facing each other in the Y direction, which are exposed from the gate lines 31, 32. This makes it possible to decrease the distance d1 in the Y direction between the active regions 2P1, 2N1 in the inverter cell C1. Thus, the area of the semiconductor integrated circuit device can be reduced.

In the nanosheet 21, an upper surface in the Y direction in the figure is covered with the gate line 31. The nanosheet 22 has a lower surface in the Y direction in the figure, which is covered with the gate line 32. The cell rows CR are disposed so as to be alternately reversed in the Y direction. That is, in the cells adjacent to each other in the Y direction, the nanosheets in the active regions facing each other in the Y direction have surfaces facing each other in the Y direction, which are not exposed from the gate lines. Thus, the distance d2 in the Y direction between the active regions in the cells adjacent to each other in the Y direction is greater than the distance d1 in the Y direction between the active regions 2P1, 2N1 in the inverter cell C1.

A distance d3 in the Y direction between the power supply lines 11, 12 formed in the BM0 wiring layer is greater than the distance d1 in the Y direction between the active regions 2P1, 2N1. That is, in plan view, the lower end of the power supply line 11 in the Y direction in the figure is disposed above the lower end of the active region 2P1 in the Y direction in the figure. In plan view, the upper end of the power supply line 12 in the Y direction in the figure is disposed below the upper end of the active region 2N1 in the Y direction in the figure. In other words, in plan view, the lower end of the active region 2P1 in the figure and the upper end of the active region 2N1 in the figure are disposed between the lower end of the power supply line 11 in the figure and the upper end of the power supply line 12 in the figure (that is, inside the power supply lines 11, 12).

The via 61 connecting the power supply line 11 and the portion of the active region 2P1 serving as the source of the transistor P1 is disposed at a center portion of the active region 2P1 in the Y direction in plan view. Specifically, a distance from the center of the via 61 in the Y direction in the figure to the upper end of the active region 2P1 in the figure and a distance from the center of the via 61 in the Y direction in the figure to the lower end of the active region 2P1 in the figure are the same distance d4. The via 62 connecting the power supply line 12 and the portion of the active region 2N1 serving as the source of the transistor N1 is disposed at a center portion of the active region 2N1 in the Y direction in plan view. Specifically, a distance from the center of the via 62 in the Y direction in the figure to the upper end of the active region 2N1 in the figure and a distance from the center of the via 62 in the Y direction in the figure to the lower end of the active region 2N1 in the figure are the same distance d5. Thus, the distances from the via 61 to both the upper and lower ends of the portion of the active region 2P1, which serves as the source of the transistor P1, in the Y direction in the figure are equal to each other. The distances from the via 62 to both the upper and lower ends of the portion of the active region 2N1, which serves as the source of the transistor N1, in the Y direction in the figure are equal to each other. As a result, the current flowing through the transistors P1, N1 is equalized in the Y direction, i.e., in the up-down direction in the figure, so that the speed of the semiconductor integrated circuit device can be increased.

In addition, in plan view, the amount of overlap of the active region 2P1 with the via 61 in the Y direction is greater than the amount of overlap of the power supply line 11 with the via 61 in the Y direction. Specifically, in plan view, a distance d6 from the lower end of the via 61 in the Y direction in the figure to the lower end of the active region 2P1 in the Y direction in the figure is greater than a distance d7 from the lower end of the via 61 in the Y direction in the figure to the lower end of the power supply line 11 in the Y direction in the figure. In addition, in plan view, the amount of overlap of the active region 2N1 with the via 62 in the Y direction is greater than the amount of overlap of the power supply line 12 with the via 62 in the Y direction. Specifically, in plan view, a distance d8 from the upper end of the via 62 in the Y direction in the figure to the upper end of the active region 2N1 in the Y direction in the figure is greater than a distance d9 from the upper end of the via 62 in the Y direction in the figure to the upper end of the power supply line 12 in the Y direction in the figure.

### Configuration of Inverter Cell C4

The inverter cell C4 has a configuration substantially similar to that of the inverter cell C1. Specifically, the inverter cell C4 has the P-type transistor P1 and the N-type transistor N1, and forms the inverter circuit having the input A and the output Y.

As shown in (b) of FIG. 2, the inverter cell C4 is different from the inverter cell C1 shown in (a) of FIG. 2 in that active regions 2P4, 2N4 having a different width in the Y direction from that of the active regions 2P1, 2N1 are disposed instead of the active regions 2P1, 2N1.

Specifically, the active regions 2P4, 2N4 have a width w1 in the Y direction. The width w2 is smaller than the width w1. That is, the drive capability of the inverter cell C4 is greater than the drive capability of the inverter cell C1.

As shown in FIG. 2, the lower end of the active region 2P4 in the Y direction in the figure is disposed at the same position in the Y direction as that of the lower end of the active region 2P1 in the Y direction in the figure. The upper end of the active region 2N4 in the Y direction in the figure is disposed at the same position in the Y direction as that of the upper end of the active region 2N1 in the Y direction in the figure. That is, the lower end of the active region 2P1 of the inverter cell C1 in the Y direction in the figure and the lower end of the active region 2P4 of the inverter cell C4 in the Y direction in the figure are aligned with each other in the Y direction. The upper end of the active region 2N1 of the inverter cell C1 in the Y direction in the figure and the upper end of the active region 2N4 of the inverter cell C4 in the Y direction in the figure are aligned with each other in the Y direction. In the inverter cells C1, C4, the lower surfaces of the nanosheets 21 in the Y direction in the figure are exposed from the gate lines 31. In the inverter cells C1, C4, the upper surfaces of the nanosheets 22 in the Y direction in the figure are exposed from the gate lines 32. That is, in the inverter cells C1, C4, the positions of the surfaces of the nanosheets exposed from the gate lines are aligned in the Y direction. Here, in the forksheet FET, the nanosheets facing each other and exposed from the gate lines are formed by providing a structure made of an insulator therebetween. Thus, as in the configuration of FIG. 1, in the cell row in which the standard cells are arranged in the X direction, the positions of the surfaces of the nanosheets exposed from the gate lines are aligned in the Y direction, so that the shape of such a structure, that is, the size and installation area thereof in the Y direction, can be made constant. This facilitates manufacturing of the semiconductor integrated circuit device.

### Other Configuration Examples

The power supply line on the back surface side of the transistor as described above may be configured using a semiconductor chip different from the semiconductor chip on which the transistor is formed.

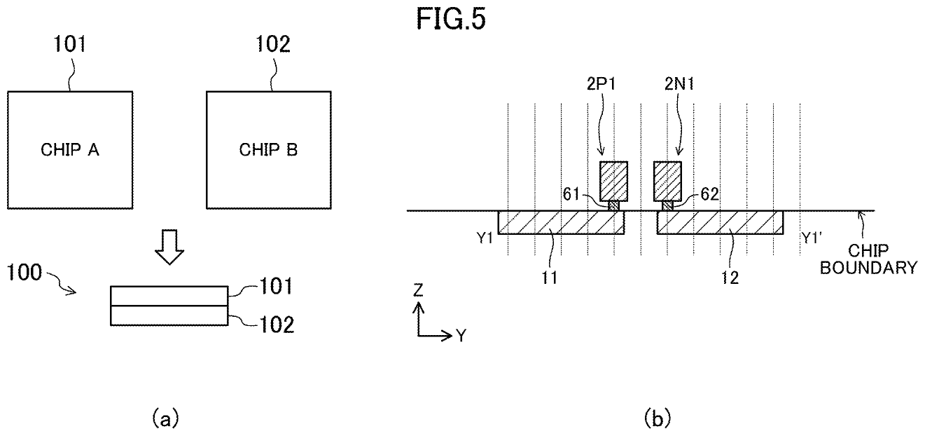

In FIG. 5, (a) is another configuration example of the semiconductor integrated circuit device according to the first embodiment. A semiconductor integrated circuit device 100 shown in (a) of FIG. 5 is formed of a first semiconductor chip 101 (chip A) and a second semiconductor chip 102 (chip B) stacked on each other. A standard cell and the like including an inverter cell as described above are disposed on the chip A. The chip B includes a power supply line in a wiring layer provided in the front surface. The chip B is bonded to the back surface side of the chip A using a bump or the like.

In FIG. 5, (b) shows a section of the inverter cell of FIG. 2 taken along line Y1-Y1′ according to this configuration example. As shown in (b) of FIG. 5, the wiring layer on the front surface of the chip B includes the power supply line 11 that supplies VDD and the power supply line 12 that supplies VSS. The power supply line 11 is connected to the active region 2P1 of the chip A through the via 61. The power supply line 12 is connected to the active region 2N1 of the chip A through the via 62.

This configuration example can also provide features and effects similar to those of the inverter cell described above.

### Variations

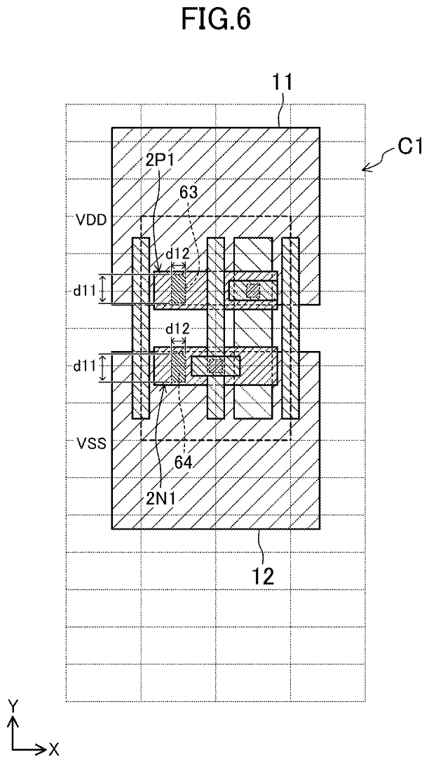

FIG. 6 is a plan view showing an example of the layout structure of the inverter cell according to a variation of the first embodiment. In FIG. 6, as compared with FIG. 2, vias 63, 64 are disposed instead of the vias 61, 62.

As shown in FIG. 6, the via 63, 64 has a rectangular section in plan view. Specifically, each of the vias 63, 64 has a length d11 in the Y direction longer than a length d12 in the X direction.

The length d11 of the via 63 in the Y direction is substantially the same as the length of the active region 2P1 from the upper end to the lower end in the figure. The length d11 of the via 64 in the Y direction is substantially the same as the length of the active region 2P1 from the upper end to the lower end in the figure.

According to the configuration of FIG. 6, since the resistance value of the via 63 connecting the power supply line 11 and the portion of the active region 2P1 serving as the source of the transistor P1 and the resistance value of the via 64 connecting the power supply line 12 and the portion of the active region 2N1 serving as the source of the transistor N1 can be reduced, a decrease in the power supply voltage can be suppressed, and occurrence of electromigration can be reduced.

Also in FIG. 6, it is preferable that the via 63 is disposed at a center portion of the active region 2P1 in the Y direction in plan view, and the via 64 is disposed at a center portion of the active region 2N1 in the Y direction in plan view.

### Other Layout Structures of Standard Cell

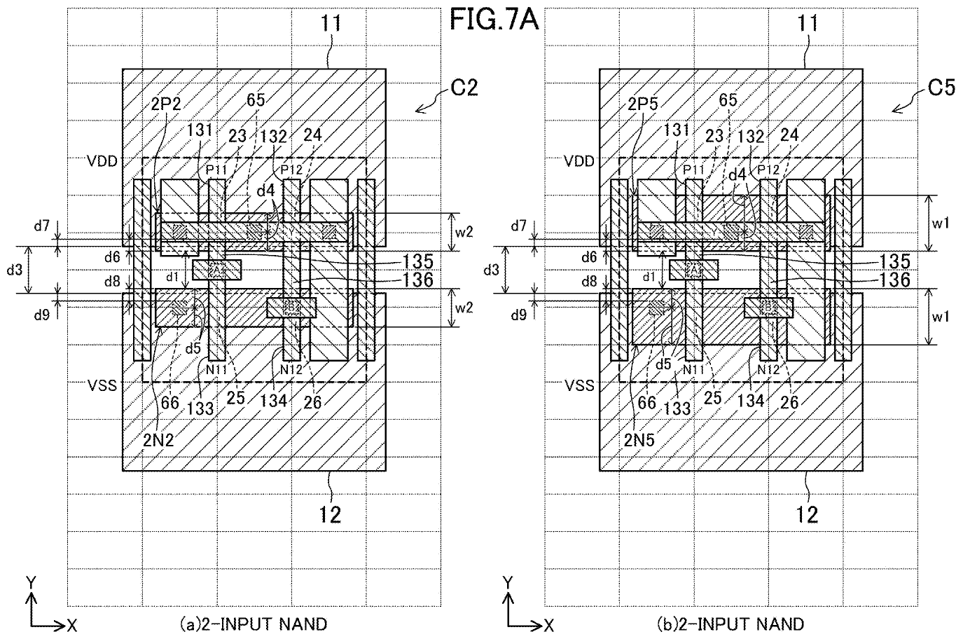

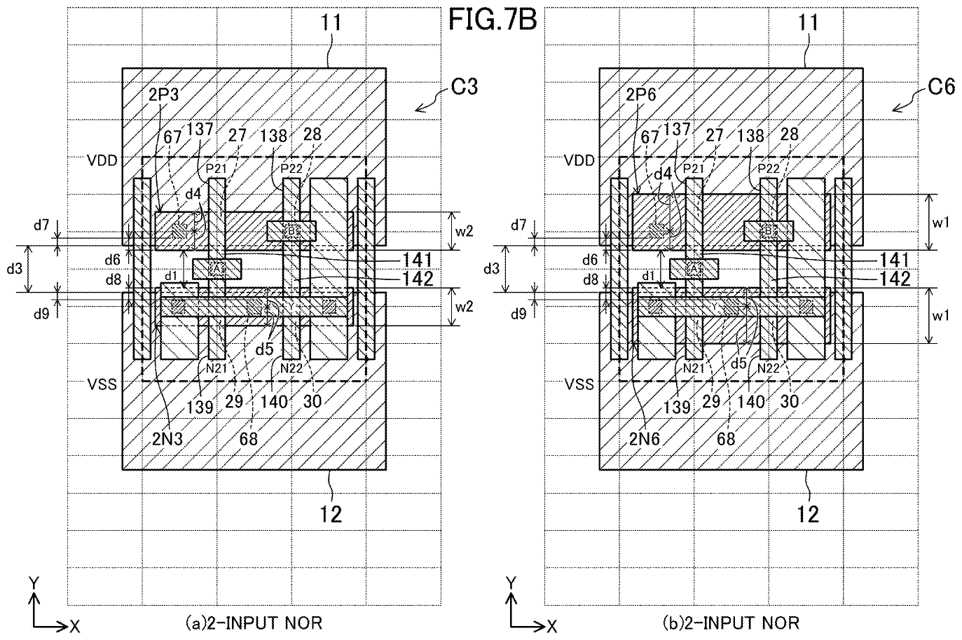

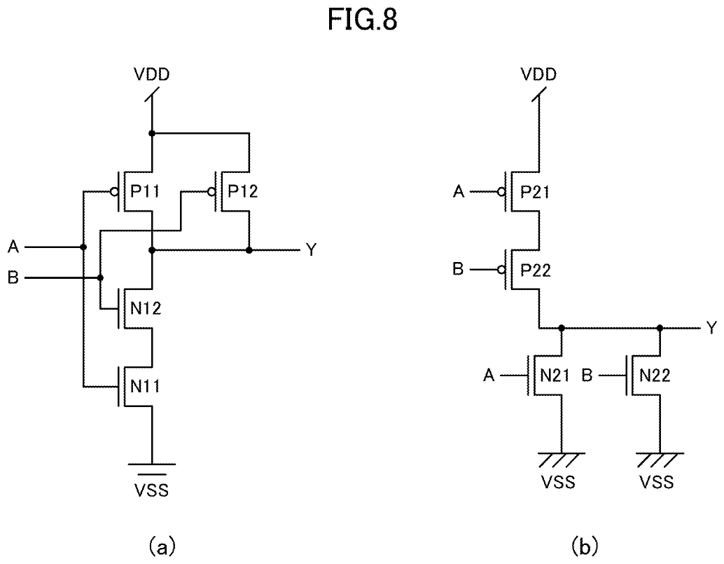

In FIGS. 7A and 7B are plan views showing examples of the layout structure of the cells in the semiconductor integrated circuit device according to the first embodiment, where (a) of FIG. 7A is a 2-input NAND cell C2, (b) of FIG. 7A is a 2-input NAND cell C5, (a) of FIG. 7B is a 2-input NOR cell C3, and (b) of FIG. 7B is a 2-input NOR cell C6. In FIG. 8, (a) is a circuit diagram of the 2-input NAND cell, and (b) is a circuit diagram of the 2-input NOR cell.

The layout structures of FIGS. 7A and 7B can be easily analogized from the above description of the inverter cell and the circuit diagrams of FIG. 8, and therefore, the description thereof will be omitted as appropriate.

### Configuration of 2-Input NAND Cell C2

In the 2-input NAND cell C2 shown in (a) of FIG. 7A, an active region 2P2 is formed in the P-type transistor region. The active region 2P2 overlaps the power supply line 11 in plan view.

The active region 2P2 includes transistors P11, P12. The transistors P11, P12 have nanosheets 23, 24 extending in the X direction, respectively. In the active region 2P2, a portion serving as the source of the transistor P11, P12 is connected to the power supply line 11 through a via 65. The via 65 is formed in an overlap region between the power supply line 11 and the active region 2P2 in plan view.

The N-type transistor region includes an active region 2N2. The active region 2N2 overlaps the power supply line 12 in plan view.

The active region 2N2 includes transistors N11, N12. The transistors N11, N12 have nanosheets 25, 26 extending in the X direction, respectively. In the active region 2N2, a portion serving as the source of the transistor N11 is connected to the power supply line 12 through a via 66. The via 66 is formed in an overlap region between the power supply line 12 and the active region 2N2 in plan view.

Gate lines 131 to 134 extending in the Y direction are formed. The nanosheets 23 to 26 overlap the gate lines 131 to 134, respectively, in plan view. The gate lines 131 to 134 correspond to the gates of the transistors P11, P12, N11, N12, respectively.

The gate lines 131, 133 are connected via a bridge portion 135 extending in the Y direction. The gate lines 132, 134 are connected via a bridge portion 136 extending in the Y direction.

The gate line 131 covers the outer periphery of the nanosheet 23 in the Y direction and the Z direction such that part of the outer periphery of the nanosheet 23 is exposed. The gate line 132 covers the outer periphery of the nanosheet 24 in the Y direction and the Z direction such that part of the outer periphery of the nanosheet 24 is exposed. The gate line 133 covers the outer periphery of the nanosheet 25 in the Y direction and the Z direction such that part of the outer periphery of the nanosheet 25 is exposed. The gate line 134 covers the outer periphery of the nanosheet 26 in the Y direction and the Z direction such that part of the outer periphery of the nanosheet 26 is exposed. Specifically, in the nanosheet 23, 24, a lower surface in the Y direction in the figure is exposed from the gate line 131, 132, and an upper surface in the Y direction in the figure is covered with the gate line 131, 132. In the nanosheet 25, 26, an upper surface in the Y direction in the figure is exposed from the gate line 133, 134, and a lower surface in the Y direction in the figure is covered with the gate line 133, 134.

As described above, the 2-input NAND cell C2 has the P-type transistors P11, P12 and the N-type transistors N11, N12, and forms a NAND circuit having inputs A, B and an output Y.

As shown in (a) of FIG. 7A, the active region 2P2, 2N2 in the 2-input NAND cell C2 has a width w2 in the Y direction in plan view.

In the 2-input NAND cell C2 of (a) of FIG. 7A, the lower surfaces of the nanosheets 23, 24 in the Y direction in the figure are exposed from the gate lines 131, 132, respectively. In the nanosheets 25, 26, the upper surfaces in the Y direction in the figure are exposed from the gate lines 133, 134, respectively. That is, the nanosheets 23, 25 have surfaces facing each other in the Y direction, which are exposed from the gate lines 131, 133. The nanosheets 24, 26 have surfaces facing each other in the Y direction, which are exposed from the gate lines 132, 134. This makes it possible to decrease the distance d1 in the Y direction between the active regions 2P2, 2N2. Thus, the area of the semiconductor integrated circuit device can be reduced.

The nanosheets 23, 24 are covered with the gate lines 131, 132 on the upper side in the Y direction in the figure, respectively. The nanosheets 25, 26 are covered with the gate lines 133, 134 on the lower side in the Y direction in the figure, respectively. The cell rows CR are disposed so as to be alternately reversed in the Y direction. That is, in the cells adjacent to each other in the Y direction, the nanosheets in the active regions facing each other in the Y direction have surfaces facing each other in the Y direction, which are not exposed from the gate lines. Thus, the distance d2 in the Y direction between the active regions in the cells adjacent to each other in the Y direction is greater than the distance d1 in the Y direction between the active regions 2P2, 2N2 in the 2-input NAND cell C2.

The distance d3 in the Y direction between the power supply lines 11, 12 formed in the BM0 wiring layer is greater than the distance d1 in the Y direction between the active regions 2P2, 2N2. That is, in plan view, the lower end of the power supply line 11 in the Y direction in the figure is disposed above the lower end of the active region 2P2 in the Y direction in the figure. In plan view, the upper end of the power supply line 12 in the Y direction in the figure is disposed below the upper end of the active region 2N2 in the Y direction in the figure. In other words, in plan view, the lower end of the active region 2P2 in the figure and the upper end of the active region 2N2 in the figure are disposed between the lower end of the power supply line 11 in the figure and the upper end of the power supply line 12 in the figure (that is, inside the power supply lines 11, 12).

The via 65 connecting the power supply line 11 and the portion of the active region 2P2 serving as the source of the transistor P11, P12 is disposed at a center portion of the active region 2P2 in the Y direction in plan view. Specifically, a distance from the center of the via 65 in the Y direction in the figure to the upper end of the active region 2P2 in the figure and a distance from the center of the via 65 in the Y direction in the figure to the lower end of the active region 2P2 in the figure are the same distance d4. The via 66 connecting the power supply line 12 and the portion of the active region 2N2 serving as the source of the transistor N11 is disposed at a center portion of the active region 2N2 in the Y direction in plan view. Specifically, a distance from the center of the via 66 in the Y direction in the figure to the upper end of the active region 2N2 in the figure and a distance from the center of the via 66 in the Y direction in the figure to the lower end of the active region 2N2 in the figure are the same distance d5. Thus, the distances from the via 65 to both the upper and lower ends of the portion of the active region 2P2, which serves as the source of the transistor P11, P12, in the Y direction in the figure are equal to each other. The distances from the via 66 to both the upper and lower ends of the portion of the active region 2N2, which serves as the source of the transistor N11, in the Y direction in the figure are equal to each other. As a result, the current flowing through the transistors P11, P12, N11 is equalized in the Y direction, i.e., in the up-down direction in the figure, so that the speed of the semiconductor integrated circuit device can be increased.

In addition, in plan view, the amount of overlap of the active region 2P2 with the via 65 in the Y direction is greater than the amount of overlap of the power supply line 11 with the via 65 in the Y direction. Specifically, in plan view, the distance d6 from the lower end of the via 65 in the Y direction in the figure to the lower end of the active region 2P2 in the Y direction in the figure is greater than the distance d7 from the lower end of the via 65 in the Y direction in the figure to the lower end of the power supply line 11 in the Y direction in the figure. In addition, in plan view, the amount of overlap of the active region 2N2 with the via 66 in the Y direction is greater than the amount of overlap of the power supply line 12 with the via 66 in the Y direction. Specifically, in plan view, the distance d8 from the upper end of the via 66 in the Y direction in the figure to the upper end of the active region 2N2 in the Y direction in the figure is greater than the distance d9 from the upper end of the via 66 in the Y direction in the figure to the upper end of the power supply line 12 in the Y direction in the figure.

### Configuration of 2-Input NAND Cell C5)

The 2-input NAND cell C5 has substantially the same configuration as that of the 2-input NAND cell C2. Specifically, the 2-input NAND cell C5 has the P-type transistors P11, P12 and the N-type transistors N11, N12, and forms a NAND circuit having inputs A, B and an output Y.

As shown in (b) of FIG. 7A, the 2-input NAND cell C5 is different from the 2-input NAND cell C2 shown in (a) of FIG. 7A in that active regions 2P5, 2N5 having a different width in the Y direction from that of the active regions 2P2, 2N2 are disposed instead of the active regions 2P2, 2N2.

Specifically, the active regions 2P5, 2N5 have a width w1 in the Y direction. The width w2 is smaller than the width w1. That is, the drive capability of the 2-input NAND cell C5 is greater than the drive capability of the 2-input NAND cell C2.

As shown in FIG. 7A, the lower end of the active region 2P5 in the Y direction in the figure is disposed at the same position in the Y direction as that of the lower end of the active region 2P2 in the Y direction in the figure. The upper end of the active region 2N5 in the Y direction in the figure is disposed at the same position in the Y direction as that of the upper end of the active region 2N2 in the Y direction in the figure. That is, the lower end of the active region 2P2 of the 2-input NAND cell C2 in the Y direction in the figure and the lower end of the active region 2P5 of the 2-input NAND cell C5 in the Y direction in the figure are aligned with each other in the Y direction. That is, the upper end of the active region 2N2 of the 2-input NAND cell C2 in the Y direction in the figure and the upper end of the active region 2N5 of the 2-input NAND cell C5 in the Y direction in the figure are aligned with each other in the Y direction. In the 2-input NAND cells C2, C5, the lower surfaces of the nanosheets 23, 24 in the Y direction in the figure are exposed from the gate lines 131, 132, respectively. In the nanosheets 25, 26 of the 2-input NAND cells C2, C5, the upper surfaces in the Y direction in the figure are exposed from the gate lines 133, 134, respectively. That is, in the 2-input NAND cells C2, C5, the positions of the surfaces of the nanosheets exposed from the gate lines are aligned in the Y direction. This makes it possible to make the shape of the structure formed of the insulator and provided between the nanosheets facing each other and exposed from the gate lines, that is, the size and the installation area in the Y direction, constant. Thus, manufacturing of the semiconductor integrated circuit device is facilitated.

### Configuration of 2-Input NOR Cell C3

In the 2-input NOR cell C3 shown in (a) of FIG. 7B, an active region 2P3 is formed in the P-type transistor region. The active region 2P3 overlaps the power supply line 11 in plan view.

The active region 2P3 includes transistors P21, P22. The transistors P21, P22 have nanosheets 27, 28 extending in the X direction, respectively. In the active region 2P3, a portion serving as the source of the transistor P21 is connected to the power supply line 11 through a via 67. The via 67 is formed in an overlap region between the power supply line 11 and the active region 2P3 in plan view.

The N-type transistor region includes an active region 2N3. The active region 2N3 overlaps the power supply line 12 in plan view.

The active region 2N3 includes transistors N21, N22. The transistors N21, N22 have nanosheets 29, 30 extending in the X direction, respectively. In the active region 2N3, a portion serving as the source of the transistor N21, N22 is connected to the power supply line 12 through a via 68. The via 68 is formed in an overlap region between the power supply line 12 and the active region 2N3 in plan view.

Gate lines 137 to 140 extending in the Y direction are formed. The nanosheets 27 to 30 overlap the gate lines 137 to 140, respectively, in plan view. The gate lines 137 to 140 correspond to the gates of the transistors P21, P22, N21, N22, respectively.

The gate lines 137, 139 are connected via a bridge portion 141 extending in the Y direction. The gate lines 138, 140 are connected via a bridge portion 142 extending in the Y direction.

The gate line 137 covers the outer periphery of the nanosheet 27 in the Y direction and the Z direction such that part of the outer periphery of the nanosheet 27 is exposed. The gate line 138 covers the outer periphery of the nanosheet 28 in the Y direction and the Z direction such that part of the outer periphery of the nanosheet 28 is exposed. The gate line 139 covers the outer periphery of the nanosheet 29 in the Y direction and the Z direction such that part of the outer periphery of the nanosheet 29 is exposed. The gate line 140 covers the outer periphery of the nanosheet 30 in the Y direction and the Z direction such that part of the outer periphery of the nanosheet 30 is exposed. Specifically, in the nanosheet 27, 28, a lower surface in the Y direction in the figure is exposed from the gate line 137, 138, and an upper surface in the Y direction in the figure is covered with the gate line 137, 138. In the nanosheet 29, 30, an upper surface in the Y direction in the figure is exposed from the gate line 139, 140, and a lower surface in the Y direction in the figure is covered with the gate line 139, 140.

As described above, the 2-input NOR cell C3 has the P-type transistors P21, P22 and the N-type transistors N21, N22, and forms a NOR circuit having inputs A, B and an output Y.

As shown in (a) of FIG. 7B, the active region 2P3, 2N3 in the 2-input NOR cell C3 have a width w2 in the Y direction in plan view.

In the 2-input NOR cell C3 of (a) of FIG. 7B, the lower surfaces of the nanosheets 27, 28 in the Y direction in the figure are exposed from the gate lines 137, 138, respectively. The upper surfaces of the nanosheets 29, 30 in the Y direction in the figure are exposed from the gate lines 139, 140, respectively. That is, the nanosheets 27, 29 have surfaces facing each other in the Y direction, which are exposed from the gate lines 137, 139. The nanosheets 28, 30 have surfaces facing each other in the Y direction, which are exposed from the gate lines 138, 140. This makes it possible to decrease the distance d1 in the Y direction between the active regions 2P3, 2N3.

In the nanosheets 27, 28, upper surfaces in the Y direction in the figure are covered with the gate lines 137, 138, respectively. The nanosheet 29, 30 has a lower surface in the Y direction in the figure, which is covered with the gate line 139, 140. The cell rows CR are disposed so as to be alternately reversed in the Y direction. That is, in the cells adjacent to each other in the Y direction, the nanosheets in the active regions facing each other in the Y direction have surfaces facing each other in the Y direction, which are not exposed from the gate lines. Thus, the distance d2 in the Y direction between the active regions in the cells adjacent to each other in the Y direction is greater than the distance d1 in the Y direction between the active regions 2P3, 2N3 in the 2-input NOR cell C3.

The distance d3 in the Y direction between the power supply lines 11, 12 formed in the BM0 wiring layer is greater than the distance d1 in the Y direction between the active regions 2P3, 2N 3. That is, in plan view, the lower end of the power supply line 11 in the Y direction in the figure is disposed above the lower end of the active region 2P3 in the Y direction in the figure. In plan view, the upper end of the power supply line 12 in the Y direction in the figure is disposed below the upper end of the active region 2N3 in the Y direction in the figure. In other words, in plan view, the lower end of the active region 2P3 in the figure and the upper end of the active region 2N3 in the figure are disposed between the lower end of the power supply line 11 in the figure and the upper end of the power supply line 12 in the figure (that is, inside the power supply lines 11, 12).

The via 67 connecting the power supply line 11 and the portion of the active region 2P3 serving as the source of the transistor P21 is disposed at a center portion of the active region 2P3 in the Y direction in plan view. Specifically, a distance from the center of the via 67 in the Y direction in the figure to the upper end of the active region 2P3 in the figure and a distance from the center of the via 67 in the Y direction in the figure to the lower end of the active region 2P3 in the figure are the same distance d4. The via 68 connecting the power supply line 12 and the portion of the active region 2N3 serving as the source of the transistor N21, N22 is disposed at a center portion of the active region 2N3 in the Y direction in plan view. Specifically, a distance from the center of the via 68 in the Y direction in the figure to the upper end of the active region 2N3 in the figure and a distance from the center of the via 68 in the Y direction in the figure to the lower end of the active region 2N3 in the figure are the same distance d5. Thus, the distances from the via 67 to both the upper and lower ends of the portion of the active region 2P3, which serves as the source of the transistor P21, in the Y direction in the figure are equal to each other. The distances from the via 68 to both the upper and lower ends of the portion of the active region 2N3, which serves as the source of the transistor N21, N22, in the Y direction in the figure are equal to each other. As a result, the current flowing through the transistors P21, N21, N22 is equalized in the Y direction, i.e., in the up-down direction in the figure, so that the speed of the semiconductor integrated circuit device can be increased.

In addition, in plan view, the amount of overlap of the active region 2P3 with the via 67 in the Y direction is greater than the amount of overlap of the power supply line 11 with the via 67 in the Y direction. Specifically, in plan view, the distance d6 from the lower end of the via 67 in the Y direction in the figure to the lower end of the active region 2P3 in the Y direction in the figure is greater than the distance d7 from the lower end of the via 67 in the Y direction in the figure to the lower end of the power supply line 11 in the Y direction in the figure. In addition, in plan view, the amount of overlap of the active region 2N3 with the via 68 in the Y direction is greater than the amount of overlap of the power supply line 12 with the via 68 in the Y direction. Specifically, in plan view, the distance d8 from the upper end of the via 68 in the Y direction in the figure to the upper end of the active region 2N3 in the Y direction in the figure is greater than the distance d9 from the upper end of the via 68 in the Y direction in the figure to the upper end of the power supply line 12 in the Y direction in the figure.

### Configuration of 2-Input NOR Cell C6

The 2-input NOR cell C6 has substantially the same configuration as that of the 2-input NOR cell C3. Specifically, the 2-input NOR cell C6 has the P-type transistors P21, P22 and the N-type transistors N21, N22, and forms a NOR circuit having inputs A, B and an output Y.

As shown in (b) of FIG. 7B, the 2-input NOR cell C6 is different from the 2-input NOR cell C3 shown in (a) of FIG. 7B in that active regions 2P6, 2N6 having a different width in the Y direction from that of the active regions 2P3, 2N3 are disposed instead of the active regions 2P3, 2N3.

Specifically, the active regions 2P6, 2N6 have a width w1 in the Y direction. The width w2 is smaller than the width w1. That is, the drive capability of the 2-input NOR cell C6 is greater than the drive capability of the 2-input NOR cell C3.

As shown in FIG. 7B, the lower end of the active region 2P6 in the Y direction in the figure is disposed at the same position in the Y direction as that of the lower end of the active region 2P3 in the Y direction in the figure. The upper end of the active region 2N6 in the Y direction in the figure is disposed at the same position in the Y direction as that of the upper end of the active region 2N3 in the Y direction in the figure. That is, the lower end of the active region 2P3 of the 2-input NOR cell C3 in the Y direction in the figure and the lower end of the active region 2P6 of the 2-input NOR cell C6 in the Y direction in the figure are aligned with each other in the Y direction. That is, the upper end of the active region 2N3 of the 2-input NOR cell C3 in the Y direction in the figure and the upper end of the active region 2N6 of the 2-input NOR cell C6 in the Y direction in the figure are aligned with each other in the Y direction. In the 2-input NOR cells C3, C6, the lower surfaces of the nanosheets 27, 28 in the Y direction in the figure are exposed from the gate lines 137, 138, respectively. In the nanosheets 29, 30 of the 2-input NOR cells C3, C6, the upper surfaces in the Y direction in the figure are exposed from the gate lines 139, 140, respectively. That is, in the 2-input NOR cells C3, C6, the positions of the surfaces of the nanosheets exposed from the gate lines are aligned in the Y direction. This makes it possible to make the shape of the structure formed of the insulator and provided between the nanosheets facing each other and exposed from the gate lines, that is, the size and the installation area in the Y direction, constant. Thus, manufacturing of the semiconductor integrated circuit device is facilitated.

### Second Embodiment

### Configuration of Circuit Block

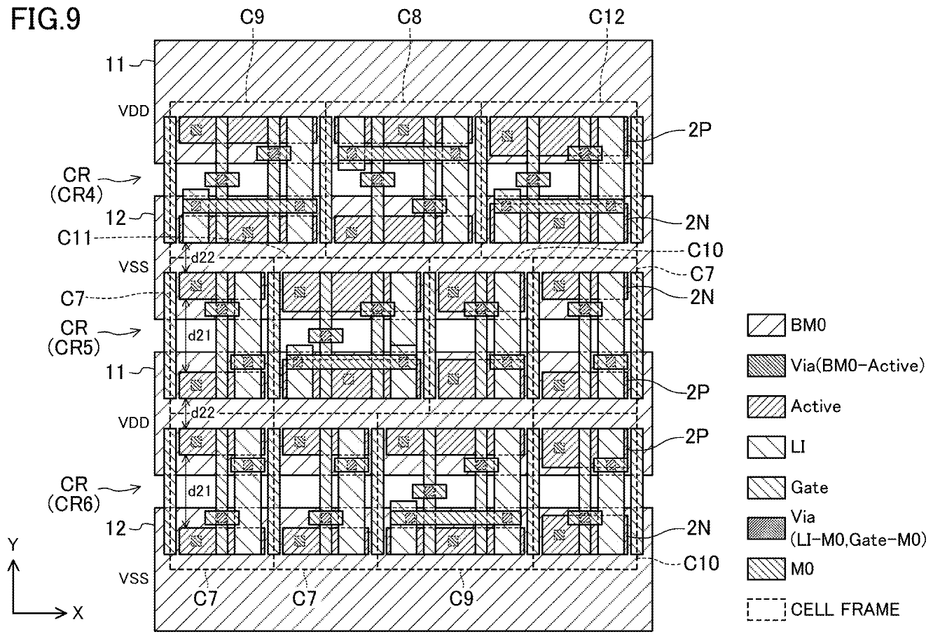

FIG. 9 is a plan view of an example of the layout of circuit blocks in a semiconductor integrated circuit device according to a second embodiment.

The block layout of FIG. 9 is formed by disposing standard cells. In the present embodiment, a power supply line is also formed in a BM0 wiring layer, which is a back wiring layer provided on the back surface of a semiconductor chip on which a transistor is formed.

In the layout of FIG. 9, a plurality of cells arranged in the X direction form a cell row CR (CR4 to CR6). A plurality of cell rows CR (three rows in FIG. 9) are disposed in the Y direction. The plurality of cells include cells having logic functions, such as an inverter, a NAND gate, and a NOR gate. For example, the cell row CR includes inverter cells C7, C10, 2-input NAND cells C8, C11, 2-input NOR cells C9, C12, and the like to be described later.

At each end of each cell in the Y direction in the BM0 wiring layer, a power supply line is formed, and power supply voltages VDD, VSS are supplied to the cell from the outside through the power supply line. The cell rows CR are disposed so as to be alternately reversed in the Y direction. At a boundary between adjacent cell rows CR, the power supply line (power supply line 11 described later) that supplies the power supply voltage VDD is continuous in the X direction, and the power supply line (power supply line 12 described later) that supplies the power supply voltage VSS is continuous in the X direction. That is, in the BM0 wiring layer, the power supply lines extending in the X direction are formed, and the power supply lines that supply the power supply voltage VDD and the power supply lines that supply the power supply voltage VSS are alternately disposed in the Y direction.

Each cell includes an active region 2P forming the channel, source, and drain of a P-type transistor, and an active region 2N forming the channel, source, and drain of an N-type transistor. In the cell row CR, the active regions 2P are arranged in the X direction, and the active regions 2N are arranged in the X direction. In the cell rows CR adjacent to each other in the Y direction, the active regions 2P are disposed so as to face each other, and the active regions 2N are disposed so as to face each other. A distance d21 in the Y direction between the active regions 2P, 2N in the cell is smaller than a distance d22 between the active regions 2P (2N) between the cell rows CR.

In the cell row CR4, CR6, the upper ends of the active regions 2P of the cells in the Y direction are arranged in the X direction, and the lower ends of the active regions 2N of the cells in the Y direction are arranged in the X direction, as shown in the figure. In the cell row CR5, the upper ends of the active regions 2N of the cells in the Y direction are arranged in the X direction, and the lower ends of the active regions 2P of the cells in the Y direction are arranged in the X direction, as shown in the figure. That is, in the cell row CR, in the cells arranged in the Y direction, the active regions 2P, 2N are arranged such that end portions thereof on the side where the active regions 2P, 2N face each other are in line in the X direction.

### Configuration of Inverter Cell C7)

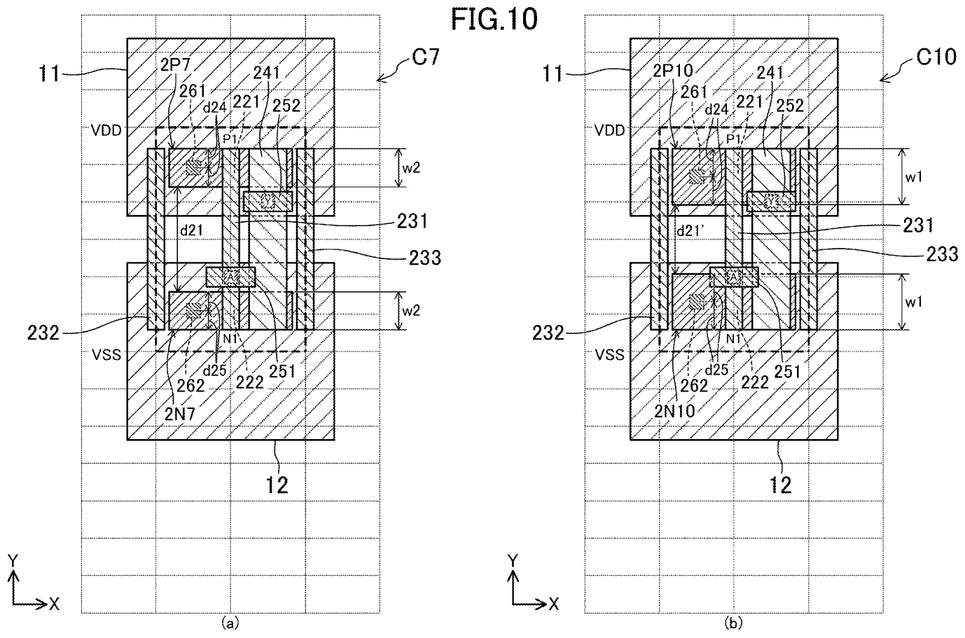

FIG. 10 shows plan views showing an example of the layout structures of the inverter cells C7, C10 according to the second embodiment. Specifically, in FIG. 10, (a) shows the inverter cell C7, and (b) shows the inverter cell C10. The inverter circuit of FIG. 4 is formed in EACH OF THE INVERTER CELLS C7, C10 of FIG. 10.

As shown in (a) of FIG. 10, the BM0 wiring layer includes the power supply lines 11, 12 extending in the X direction at both ends of the cell in the Y direction in the figure. The power supply line 11 supplies the power supply voltage VDD. The power supply line 12 supplies the power supply voltage VSS.

The P-type transistor region includes an active region 2P7. The active region 2P7 overlaps the power supply line 11 in plan view.

The active region 2P7 includes a transistor P1. The transistor P1 has a nanosheet 221 extending in the X direction. In the active region 2P7, a portion serving as the source of the transistor P1 is connected to the power supply line 11 through a via 261. The via 261 is formed in an overlap region between the power supply line 11 and the active region 2P7 in plan view.

The N-type transistor region includes an active region 2N7. The active region 2N7 overlaps the power supply line 12 in plan view.

The active region 2N7 includes a transistor N1. The transistor N1 has a nanosheet 222 extending in the X direction. In the active region 2N7, a portion serving as the source of the transistor N1 is connected to the power supply line 12 through a via 262. The via 262 is formed in an overlap region between the power supply line 12 and the active region 2N7 in plan view.

A gate line 231 extending in the Y direction is formed at a cell center portion in the X direction. The nanosheets 221, 222 overlap the gate line 231 in plan view. The gate line 231 corresponds to the gates of the transistors P1, N1.

The gate line 231 covers the outer peripheries of the nanosheets 221, 222 in the Y direction and the Z direction such that part of the outer peripheries of the nanosheets 221, 222 is exposed. Specifically, in the nanosheet 221, an upper surface in the Y direction in the figure is exposed from the gate line 231, and a lower surface in the Y direction in the figure is covered with the gate line 231. In the nanosheet 222, a lower surface in the Y direction in the figure is exposed from the gate line 231, and an upper surface in the Y direction in the figure is covered with the gate line 231.

Dummy gate lines 232, 233 are formed on the cell frames on both sides in the X direction. The dummy gate line 232 is shared with other cells disposed on the left side in the figure. The dummy gate line 233 is shared with other cells disposed on the right side in the figure.

In a local wiring layer, a local line 241 extending in the Y direction is formed. The local line 241 is connected to the portion of the active region 2P 7 serving as the drain of the transistor P1 and the portion of the active region 2N7 serving as the drain of the transistor N1.

In the M0 wiring layer, lines 251, 252 extending in the X direction are formed. The line 251 is connected to the gate line 231 through a via. The line 252 is connected to the local line 241 through a via. The line 251 corresponds to the input A, and the line 252 corresponds to the output Y.

As described above, the inverter cell C7 has the P-type transistor P1 and the N-type transistor N1, and forms the inverter circuit having the input A and the output Y.

As shown in (a) of FIG. 10, the active region 2P7, 2N7 in the inverter cell C7 has a width w2 in the Y direction in plan view.

In the inverter cell C7 of (a) of FIG. 10, the upper surface of the nanosheet 221 in the Y direction in the figure is exposed from the gate line 231. The nanosheet 222 has a lower surface in the Y direction in the figure, which is exposed from the gate line 231. The cell rows CR are disposed so as to be alternately reversed in the Y direction. That is, in the cells adjacent to each other in the Y direction, the nanosheets in the active regions facing each other in the Y direction have surfaces facing each other in the Y direction, which are exposed from the gate lines. This makes it possible to decrease the distance d22 between the active regions facing each other in the Y direction in the cells adjacent to each other in the Y direction. Thus, the area of the semiconductor integrated circuit device can be reduced.

The nanosheet 221 has a lower surface in the Y direction in the figure, which is covered with the gate line 231. An upper surface of the nanosheet 222 in the Y direction in the figure is covered with the gate line 231. That is, in the inverter cell C7, the nanosheets 221, 222 have surfaces facing each other, which are covered with the gate line 231. Thus, the distance d21 in the Y direction between the active regions 2P7, 2N7 in the inverter cell C10 is greater than the distance d22 in the Y direction between the active regions in the cells adjacent to each other in the Y direction.

The via 261 connecting the power supply line 11 and the portion of the active region 2P7 serving as the source of the transistor P1 is disposed at a center portion of the active region 2P7 in the Y direction in plan view. Specifically, a distance from the center of the via 261 in the Y direction in the figure to the upper end of the active region 2P7 in the figure and a distance from the center of the via 261 in the Y direction in the figure to the lower end of the active region 2P7 in the figure are the same distance d24. The via 262 connecting the power supply line 12 and the portion of the active region 2N7 serving as the source of the transistor N1 is disposed at a center portion of the active region 2N7 in the Y direction in plan view. Specifically, a distance from the center of the via 262 in the Y direction in the figure to the upper end of the active region 2N7 in the figure and a distance from the center of the via 262 in the Y direction in the figure to the lower end of the active region 2N7 in the figure are the same distance d25. Thus, the distances from the via 261 to both the upper and lower ends of the portion of the active region 2P7, which serves as the source of the transistor P1, in the Y direction in the figure are equal to each other. The distances from the via 262 to both the upper and lower ends of the portion of the active region 2N7, which serves as the source of the transistor N1, in the Y direction in the figure are equal to each other. As a result, the current flowing through the transistors P1, N1 is equalized in the Y direction, i.e., in the up-down direction in the figure, so that the speed of the semiconductor integrated circuit device can be increased.

### Configuration of Inverter Cell C10

The inverter cell C10 has a configuration substantially similar to that of the inverter cell C7. Specifically, the inverter cell C10 has the P-type transistor P1 and the N-type transistor N1, and forms the inverter circuit having the input A and the output Y.

As shown in (b) FIG. 10, the inverter cell C10 is different from the inverter cell C7 shown in (a) of FIG. 10 in that active regions 2P10, 2N10 having a different width in the Y direction from that of the active regions 2P7, 2N7 are disposed instead of the active regions 2P7, 2N7.

Specifically, the active regions 2P10, 2N10 have a width w1 in the Y direction. The width w2 is smaller than the width w1. That is, the drive capability of the inverter cell C10 is greater than the drive capability of the inverter cell C7.

As shown in FIG. 10, the upper end of the active region 2P10 in the Y direction in the figure is disposed at the same position in the Y direction as that of the upper end of the active region 2P7 in the Y direction in the figure. The lower end of the active region 2N10 in the Y direction in the figure is disposed at the same position in the Y direction as that of the lower end of the active region 2N7 in the Y direction in the figure. That is, the upper end of the active region 2P7 of the inverter cell C7 in the Y direction in the figure and the upper end of the active region 2P10 of the inverter cell C10 in the Y direction in the figure are aligned with each other in the Y direction. The lower end of the active region 2N7 of the inverter cell C7 in the Y direction in the figure and the lower end of the active region 2N10 of the inverter cell C10 in the Y direction in the figure are aligned with each other in the Y direction. In the nanosheets 221 of the inverter cells C7, C10, the upper surfaces in the Y direction in the figure are exposed from the gate lines 231. In the inverter cells C7, C10, the lower surfaces of the nanosheets 222 in the Y direction in the figure are exposed from the gate lines 231. That is, in the inverter cells C7, C10, the positions of the surfaces of the nanosheets exposed from the gate lines are aligned in the Y direction. This makes it possible to make the shape of the structure formed of the insulator and provided between the nanosheets facing each other and exposed from the gate lines, that is, the size and the installation area in the Y direction, constant. Thus, manufacturing of the semiconductor integrated circuit device is facilitated.

### Other Layout Structures of Standard Cell

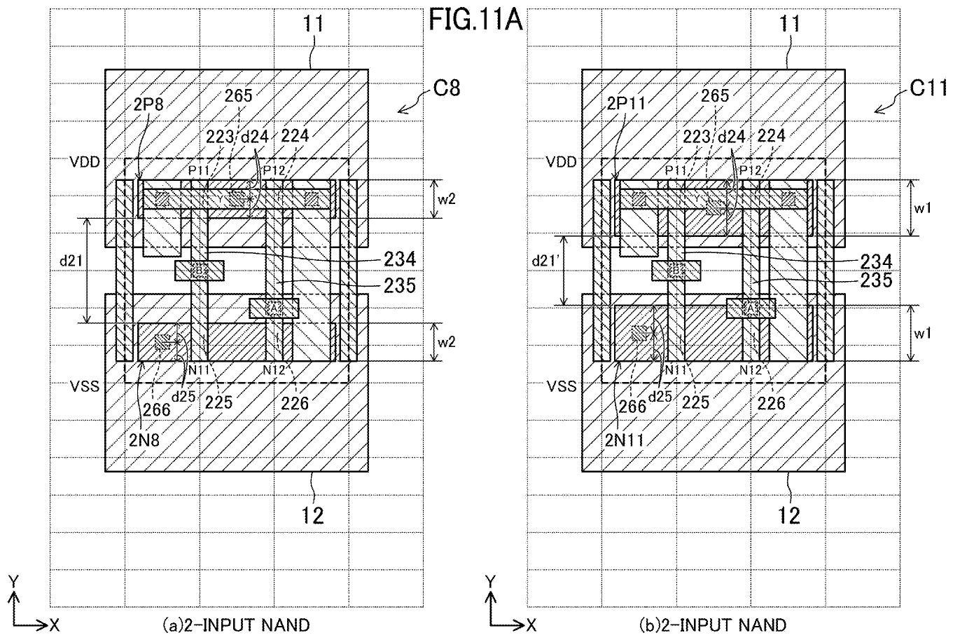

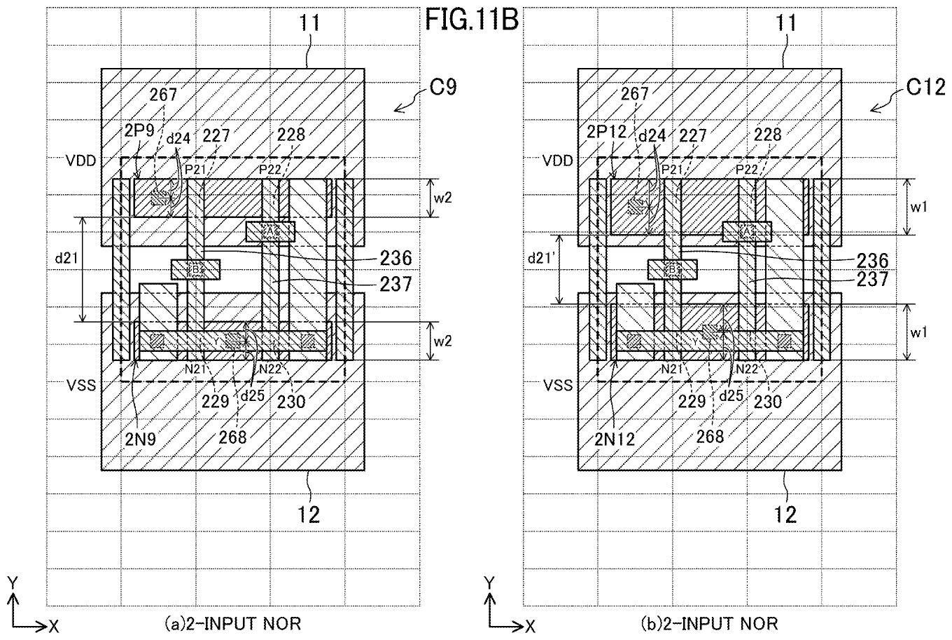

FIGS. 11A and 11B are plan views showing examples of the layout structure of the cells in the semiconductor integrated circuit device according to the second embodiment, where (a) of FIG. 11A is a 2-input NAND cell C8, (b) of FIG. 11A is a 2-input NAND cell C11, (a) of FIG. 11B is a 2-input NOR cell C9, and (b) of FIG. 11B is a 2-input NOR cell C12.

The layout structures of FIGS. 11A and 11B can be easily analogized from the above description of the inverter cell and the circuit diagrams of FIGS. 8A and 8B, and therefore, the description thereof will be omitted as appropriate.

### Configuration of 2-Input NAND Cell C8

In the 2-input NAND cell C8 shown in (a) of FIG. 11A, an active region 2P8 is formed in the P-type transistor region. The active region 2P8 overlaps the power supply line 11 in plan view.

The active region 2P8 includes transistors P11, P12. The transistors P11, P12 have nanosheets 223, 224 extending in the X direction, respectively. In the active region 2P8, a portion serving as the source of the transistor P11, P12 is connected to the power supply line 11 through a via 265. The via 265 is formed in an overlap region between the power supply line 11 and the active region 2P8 in plan view.

The N-type transistor region includes an active region 2N8. The active region 2N8 overlaps the power supply line 12 in plan view.

The active region 2N8 includes transistors N11, N12. The transistors N11, N12 have nanosheets 225, 226 extending in the X direction, respectively. In the active region 2N8, a portion serving as the source of the transistor N11 is connected to the power supply line 12 through a via 266. The via 266 is formed in an overlap region between the power supply line 12 and the active region 2N8 in plan view.

Gate lines 234, 235 extending in the Y direction are formed. The nanosheets 223, 225 overlap the gate line 234 in plan view. The nanosheets 224, 226 overlap the gate line 235 in plan view. The gate line 234 corresponds to the gates of the transistors P11, N11. The gate line 235 corresponds to the gates of the transistors P12, N12.

The gate line 234 covers the outer peripheries of the nanosheets 223, 225 in the Y direction and the Z direction such that part of the outer peripheries of the nanosheets 223, 225 is exposed. The gate line 235 covers the outer peripheries of the nanosheets 224, 226 in the Y direction and the Z direction such that part of the outer peripheries of the nanosheets 224, 226 is exposed. Specifically, in the nanosheet 223, 224, an upper surface in the Y direction in the figure is exposed from the gate line 234, 235, and a lower surface in the Y direction in the figure is covered with the gate line 234, 235. In the nanosheet 225, 226, a lower surface in the Y direction in the figure is exposed from the gate line 234, 235, and an upper surface in the Y direction in the figure is covered with the gate line 234, 235.

As described above, the 2-input NAND cell C8 has the P-type transistors P11, P12 and the N-type transistors N11, N12, and forms a NAND circuit having inputs A, B and an output Y.

As shown in (a) of FIG. 11A, the active region 2P8, 2N8 in the 2-input NAND cell C8 has a width w2 in the Y direction in plan view.

In the nanosheets 223, 224 of the 2-input NAND cell C8 of (a) of FIG. 11A, the upper surfaces in the Y direction in the figure are exposed from the gate lines 234, 235, respectively. The lower surfaces of the nanosheets 225, 226 in the Y direction in the figure are exposed from the gate lines 234, 235, respectively. That is, in the cells adjacent to each other in the Y direction, the nanosheets in the active regions facing each other in the Y direction have surfaces facing each other in the Y direction, which are exposed from the gate lines. This makes it possible to decrease the distance d22 between the active regions facing each other in the Y direction in the cells adjacent to each other in the Y direction. Thus, the area of the semiconductor integrated circuit device can be reduced.

The nanosheets 223, 224 are covered with the gate lines 234, 235 on the lower side in the Y direction in the figure, respectively. The nanosheets 225, 226 are covered with the gate lines 234, 235 on the upper side in the Y direction in the figure, respectively. That is, in the 2-input NAND cell C8, the nanosheets 223, 225 have surfaces facing each other, which are covered with the gate line 234. The nanosheets 224, 226 have surfaces facing each other, which are covered with the gate line 235. Thus, the distance d21 in the Y direction between the active regions 2P8, 2N8 in the 2-input NAND cell C8 is greater than the distance d22 in the Y direction between the active regions in the cells adjacent to each other in the Y direction.

The via 265 connecting the power supply line 11 and the portion of the active region 2P8 serving as the source of the transistor P11, P12 is disposed at a center portion of the active region 2P8 in the Y direction in plan view. Specifically, a distance from the center of the via 265 in the Y direction in the figure to the upper end of the active region 2P8 in the figure and a distance from the center of the via 265 in the Y direction in the figure to the lower end of the active region 2P8 in the figure are the same distance d24. The via 266 connecting the power supply line 12 and the portion of the active region 2N8 serving as the source of the transistor N11 is disposed at a center portion of the active region 2N8 in the Y direction in plan view. Specifically, a distance from the center of the via 266 in the Y direction in the figure to the upper end of the active region 2N8 in the figure and a distance from the center of the via 266 in the Y direction in the figure to the lower end of the active region 2N8 in the figure are the same distance d25. Thus, the distances from the via 265 to both the upper and lower ends of the portion of the active region 2P8, which serves as the source of the transistor P11, P12, in the Y direction in the figure are equal to each other. The distances from the via 266 to both the upper and lower ends of the portion of the active region 2N8, which serves as the source of the transistor N11, in the Y direction in the figure are equal to each other. As a result, the current flowing through the transistors P11, P12, N11 is equalized in the Y direction, i.e., in the up-down direction in the figure, so that the speed of the semiconductor integrated circuit device can be increased.

### Configuration of 2-Input NAND Cell C11

The 2-input NAND cell C11 has substantially the same configuration as that of the 2-input NAND cell C8. Specifically, the 2-input NAND cell C11 has the P-type transistors P11, P12 and the N-type transistors N11, N12, and forms a NAND circuit having inputs A, B and an output Y.

As shown in (b) of FIG. 11A, the 2-input NAND cell C11 is different from the 2-input NAND cell C8 shown in (a) of FIG. 11A in that active regions 2P11, 2N11 having a different width in the Y direction from that of the active regions 2P8, 2N8 are disposed instead of the active regions 2P8, 2N8.

Specifically, the active regions 2P11, 2N11 have a width w1 in the Y direction. The width w2 is smaller than the width w1. That is, the drive capability of the 2-input NAND cell C11 is greater than the drive capability of the 2-input NAND cell C8.

As shown in FIG. 11A, the upper end of the active region 2P11 in the Y direction in the figure is disposed at the same position in the Y direction as that of the upper end of the active region 2P8 in the Y direction in the figure. The lower end of the active region 2N11 in the Y direction in the figure is disposed at the same position in the Y direction as that of the lower end of the active region 2N8 in the Y direction in the figure. That is, the upper end of the active region 2P8 of the 2-input NAND cell C8 in the Y direction in the figure and the upper end of the active region 2P11 of the 2-input NAND cell C11 in the Y direction in the figure are aligned with each other in the Y direction. The lower end of the active region 2N8 of the 2-input NAND cell C8 in the Y direction in the figure and the lower end of the active region 2N11 of the 2-input NAND cell C11 in the Y direction in the figure are aligned with each other in the Y direction. In the nanosheets 223, 224 of the 2-input NAND cells C8, C11, the upper surfaces in the Y direction in the figure are exposed from the gate lines 234, 235, respectively. In the 2-input NAND cells C8, C11, the lower surfaces of the nanosheets 225, 226 in the Y direction in the figure are exposed from the gate lines 234, 235, respectively. That is, in the 2-input NAND cells C8, C11, the positions of the surfaces of the nanosheets exposed from the gate lines are aligned in the Y direction. This makes it possible to make the shape of the structure formed of the insulator and provided between the nanosheets facing each other and exposed from the gate lines, that is, the size and the installation area in the Y direction, constant. Thus, manufacturing of the semiconductor integrated circuit device is facilitated.

### Configuration of 2-Input NOR Cell C9

In the 2-input NOR cell C9 shown in (a) of FIG. 11B, an active region 2P9 is formed in the P-type transistor region. The active region 2P 9 overlaps the power supply line 11 in plan view.

The active region 2P9 includes transistors P21, P22. The transistors P21, P22 have nanosheets 227, 228 extending in the X direction, respectively. In the active region 2P9, a portion serving as the source of the transistor P21 is connected to the power supply line 11 through a via 267. The via 267 is formed in an overlap region between the power supply line 11 and the active region 2P9 in plan view.

The N-type transistor region includes an active region 2N9. The active region 2N9 overlaps the power supply line 12 in plan view.

The active region 2N9 includes transistors N21, N22. The transistors N21, N22 have nanosheets 229, 230 extending in the X direction, respectively. In the active region 2N9, a portion serving as the source of the transistor N21, N22 is connected to the power supply line 12 through a via 268. The via 268 is formed in an overlap region between the power supply line 12 and the active region 2N9 in plan view.

Gate lines 236, 237 extending in the Y direction are formed. The nanosheets 227, 229 overlap the gate line 236 in plan view. The nanosheets 228, 230 overlap the gate line 237 in plan view. The gate line 236 corresponds to the gates of the transistors P21, N21. The gate line 237 corresponds to the gates of the transistors P22, N22.

The gate line 236 covers the outer peripheries of the nanosheets 227, 229 in the Y direction and the Z direction such that part of the outer peripheries of the nanosheets 227, 229 is exposed. The gate line 237 covers the outer peripheries of the nanosheets 228, 230 in the Y direction and the Z direction such that part of the outer peripheries of the nanosheets 228, 230 is exposed. Specifically, in the nanosheet 227, 228, an upper surface in the Y direction in the figure is exposed from the gate line 236, 237, and a lower surface in the Y direction in the figure is covered with the gate line 236, 237. In the nanosheet 229, 230, a lower surface in the Y direction in the figure is exposed from the gate line 236, 237, and an upper surface in the Y direction in the figure is covered with the gate line 236, 237.

As described above, the 2-input NOR cell C9 has the P-type transistors P21, P22 and the N-type transistors N21, N22, and forms a NOR circuit having inputs A, B and an output Y.

As shown in (a) of FIG. 11B, the active region 2P9, 2N9 in the 2-input NOR cell C9 has a width w2 in the Y direction in plan view.

In the nanosheets 227, 228 of the 2-input NOR cell C9 of (a) of FIG. 11B, the upper surfaces in the Y direction in the figure are exposed from the gate lines 236, 237, respectively. The lower surfaces of the nanosheets 229, 230 in the Y direction in the figure are exposed from the gate lines 236, 237, respectively. That is, in the cells adjacent to each other in the Y direction, the nanosheets in the active regions facing each other in the Y direction have surfaces facing each other in the Y direction, which are exposed from the gate lines. This makes it possible to decrease the distance d22 between the active regions facing each other in the Y direction in the cells adjacent to each other in the Y direction. Thus, the area of the semiconductor integrated circuit device can be reduced.

The nanosheets 227, 228 are covered with the gate lines 236, 237 on the lower side in the Y direction in the figure, respectively. The nanosheets 229, 230 are covered with the gate lines 236, 237 on the upper side in the Y direction in the figure, respectively. That is, in the 2-input NOR cell C9, the nanosheets 227, 229 have surfaces facing each other, which are covered with the gate line 236. The nanosheets 228, 230 have surfaces facing each other, which are covered with the gate line 237. Thus, the distance d21 in the Y direction between the active regions 2P9, 2N9 in the 2-input NOR cell C9 is greater than the distance d22 in the Y direction between the active regions in the cells adjacent to each other in the Y direction.

The via 267 connecting the power supply line 11 and the portion of the active region 2P9 serving as the source of the transistor P21 is disposed at a center portion of the active region 2P9 in the Y direction in plan view. Specifically, a distance from the center of the via 267 in the Y direction in the figure to the upper end of the active region 2P9 in the figure and a distance from the center of the via 267 in the Y direction in the figure to the lower end of the active region 2P9 in the figure are the same distance d24. The via 268 connecting the power supply line 12 and the portion of the active region 2N9 serving as the source of the transistor N21, N22 is disposed at a center portion of the active region 2N9 in the Y direction in plan view. Specifically, a distance from the center of the via 268 in the Y direction in the figure to the upper end of the active region 2N9 in the figure and a distance from the center of the via 268 in the Y direction in the figure to the lower end of the active region 2N9 in the figure are the same distance d25. Thus, the distances from the via 267 to both the upper and lower ends of the portion of the active region 2P9, which serves as the source of the transistor P21, in the Y direction in the figure are equal to each other. The distances from the via 268 to both the upper and lower ends of the portion of the active region 2N9, which serves as the source of the transistor N21, N22, in the Y direction in the figure are equal to each other. As a result, the current flowing through the transistors P21, N21, N22 is equalized in the Y direction, i.e., in the up-down direction in the figure, so that the speed of the semiconductor integrated circuit device can be increased.

### Configuration of 2-Input NOR Cell C12

The 2-input NOR cell C12 has substantially the same configuration as that of the 2-input NOR cell C9. Specifically, the 2-input NOR cell C12 has the P-type transistors P21, P22 and the N-type transistors N21, N22, and forms a NOR circuit having inputs A, B and an output Y.

As shown in (b) of FIG. 11B, the 2-input NOR cell C12 is different from the 2-input NOR cell C9 shown in (a) of FIG. 11B in that active regions 2P12, 2N12 having a different width in the Y direction from that of the active regions 2P9, 2N9 are disposed instead of the active regions 2P9, 2N9.

Specifically, the active regions 2P12, 2N12 have a width w1 in the Y direction. The width w2 is smaller than the width w1. That is, the drive capability of the 2-input NOR cell C12 is greater than the drive capability of the 2-input NOR cell C9.

As shown in FIG. 11B, the upper end of the active region 2P12 in the Y direction in the figure is disposed at the same position in the Y direction as that of the upper end of the active region 2P9 in the Y direction in the figure. The lower end of the active region 2N12 in the Y direction in the figure is disposed at the same position in the Y direction as that of the lower end of the active region 2N9 in the Y direction in the figure. That is, the upper end of the active region 2P9 of the 2-input NOR cell C9 in the Y direction in the figure and the upper end of the active region 2P12 of the 2-input NOR cell C12 in the Y direction in the figure are aligned with each other in the Y direction. The lower end of the active region 2N9 of the 2-input NOR cell C9 in the Y direction in the figure and the lower end of the active region 2N12 of the 2-input NOR cell C12 in the Y direction in the figure are aligned with each other in the Y direction. In the nanosheets 227, 228 of the 2-input NOR cells C9, C12, the upper surfaces in the Y direction in the figure are exposed from the gate lines 236, 237, respectively. In the 2-input NOR cells C9, C12, the lower surfaces of the nanosheets 229, 230 in the Y direction in the figure are exposed from the gate lines 236, 237, respectively. That is, in the 2-input NOR cells C9, C12, the positions of the surfaces of the nanosheets exposed from the gate lines are aligned in the Y direction. This makes it possible to make the shape of the structure formed of the insulator and provided between the nanosheets facing each other and exposed from the gate lines, that is, the size and the installation area in the Y direction, constant. Thus, manufacturing of the semiconductor integrated circuit device is facilitated.

In the above embodiments and variations, each transistor includes three nanosheets, but some or all of the transistors may include one, two, four, or more nanosheets.

In the above embodiments and variations, the sectional shape of the nanosheet is rectangular, but is not limited to this shape. For example, the shape may be square, circular, or elliptical.

In the 2-input NAND cells C2, C5, a via having a greater length in the Y direction than a length in the X direction, such as the via 63, 64 shown in the variation of FIG. 6, may be used instead of the via 65, 66. Similarly, in the 2-input NOR cells C3, C6, the via 63, 64 may be used instead of the via 67, 68. In the inverter cell C4, the via 63, 64 may be used instead of the via 61, 62. In the 2-input NAND cells C8, C11, the via 63, 64 may be used instead of the via 265, 266. In the 2-input NOR cells C9, C12, the via 63, 64 may be used instead of the via 267, 268.

The present disclosure enables, in a semiconductor integrated circuit device including a standard cell using a forksheet transistor and a back line, reduction in the area of the semiconductor integrated circuit device and increase in speed of the semiconductor integrated circuit device.

What is claimed is:

1. A semiconductor integrated circuit device including: a plurality of standard cells including a first standard cell,
the first standard cell including:
a first active region forming a channel, a source, and a drain of a first transistor of a first conductivity type and having a first nanosheet extending in a first direction as the channel;
a second active region forming a channel, a source, and a drain of a second transistor of a second conductivity type which is a conductivity type different from the first conductivity type and having a second nanosheet extending in the first direction as the channel;
a first gate line extending in a second direction perpendicular to the first direction and surrounding an outer periphery of the first nanosheet in the second direction and a third direction perpendicular to the first direction and the second direction;
a second gate line extending in the second direction and surrounding an outer periphery of the second nanosheet in the second direction and the third direction;
a first power supply line formed on a back surface side of the first transistor and extending in the first direction;
a second power supply line formed on a back surface side of the second transistor and extending in the first direction; and
a first via formed in an overlap region between a region of the first active region serving as the source of the first transistor and the first power supply line, the first via connecting the source in the first active region and the first power supply line,
the second nanosheet being disposed on a first side of the first nanosheet, which is one side in the second direction,
a surface of the first nanosheet on the first side being exposed from the first gate line,
a surface of the second nanosheet on a second side which is the other side in the second direction being exposed from the second gate line, and
the first via being disposed at a center portion of the first active region in the second direction in plan view.

2. The semiconductor integrated circuit device of claim 1, wherein
the first standard cell further includes:
a second via formed in an overlap region between a region of the second active region serving as the source of the second transistor and the second power supply line, the second via connecting the source in the second active region and the second power supply line, and
the second via is disposed at a center portion of the second active region in the second direction in plan view.

3. The semiconductor integrated circuit device of claim 1, wherein
the plurality of standard cells further include a second standard cell disposed adjacent to the second side of the first standard cell,
the second standard cell includes:
a third active region forming a channel, a source, and a drain of a third transistor of the first conductivity type and having a third nanosheet extending in the first direction as the channel; and
a third gate line extending in the second direction and surrounding an outer periphery of the third nanosheet in the second direction and the third direction,
a surface of the third nanosheet on the second side is exposed from the third gate line, and
a distance in the second direction between the first active region and the third active region is greater than a distance in the second direction between the first active region and the second active region.

4. The semiconductor integrated circuit device of claim 1, wherein
in plan view, an end of the first active region on the first side and an end of the second active region on the second side are disposed between an end of the first power supply line on the first side and an end of the second power supply line on the second side.

5. The semiconductor integrated circuit device of claim 1, wherein
the first via has a longer length in the second direction than a length in the first direction.

6. The semiconductor integrated circuit device of claim 1, wherein
the first active region includes a fourth nanosheet forming a channel, a source, and a drain of a fourth transistor of the first conductivity type and extending in the first direction as the channel,
the second active region includes a fifth nanosheet forming a channel, a source, and a drain of a fifth transistor of the second conductivity type and extending in the first direction as the channel,
the first standard cell further includes:
a fourth gate line extending in the second direction and surrounding an outer periphery of the fourth nanosheet in the second direction and the third direction; and
a fifth gate line extending in the second direction and surrounding an outer periphery of the fifth nanosheet in the second direction and the third direction,
the first power supply line is formed on a back surface side of the fourth transistor,
the second power supply line is formed on a back surface side of the fifth transistor,
the fifth nanosheet is disposed on the first side of the fourth nanosheet,
a surface of the fourth nanosheet on the first side is exposed from the fourth gate line, and
a surface of the fifth nanosheet on the second side is exposed from the fifth gate line.

7. The semiconductor integrated circuit device of claim 1, wherein
the plurality of standard cells further include a third standard cell disposed side by side with the first standard cell in the first direction,
the third standard cell includes:
a fourth active region forming a channel, a source, and a drain of a sixth transistor of the first conductivity type and having a sixth nanosheet extending in the first direction as the channel;
a fifth active region forming a channel, a source, and a drain of a seventh transistor of the second conductivity type and having a seventh nanosheet extending in the first direction as the channel;
a sixth gate line extending in the second direction and surrounding an outer periphery of the sixth nanosheet in the second direction and the third direction; and
a seventh gate line extending in the second direction and surrounding an outer periphery of the seventh nanosheet in the second direction and the third direction,
the seventh nanosheet is disposed on the first side of the sixth nanosheet,
a surface of the sixth nanosheet on the first side is exposed from the sixth gate line,
a surface of the seventh nanosheet on the second side is exposed from the seventh gate line,
in plan view, a width of the sixth nanosheet in the second direction is greater than a width of the first nanosheet in the second direction, and
in plan view, an end portion of the first nanosheet on the first side and an end portion of the sixth nanosheet on the first side are disposed at the same position in the second direction.

8. A semiconductor integrated circuit device including: a plurality of standard cells including a first standard cell,
the first standard cell including:
a first active region forming a channel, a source, and a drain of a first transistor of a first conductivity type and having a first nanosheet extending in a first direction as the channel;
a second active region forming a channel, a source, and a drain of a second transistor of a second conductivity type which is a conductivity type different from the first conductivity type and having a second nanosheet extending in the first direction as the channel;
a first gate line extending in a second direction perpendicular to the first direction and surrounding an outer periphery of the first nanosheet in the second direction and a third direction perpendicular to the first direction and the second direction;
a second gate line extending in the second direction and surrounding an outer periphery of the second nanosheet in the second direction and the third direction;
a first power supply line formed on a back surface side of the first transistor and extending in the first direction;
a second power supply line formed on a back surface side of the second transistor and extending in the first direction; and
a first via formed in an overlap region between a region of the first active region serving as the source of the first transistor and the first power supply line, the first via connecting the source in the first active region and the first power supply line,
the second nanosheet being disposed on a first side of the first nanosheet, which is one side in the second direction,
a surface of the first nanosheet on the first side is exposed from the first gate line,
a surface of the second nanosheet on a second side which is the other side in the second direction being exposed from the second gate line, and
an amount of overlap of the first active region on the first side in the second direction with the first via is greater than an amount of overlap of the first power supply line on the first side in the second direction with the first via.

9. The semiconductor integrated circuit device of claim 8, wherein
the first standard cell further includes:
a second via formed in an overlap region between a region of the second active region serving as the source of the second transistor and the second power supply line, the second via connecting the source in the second active region and the second power supply line, and
an amount of overlap of the second active region on the second side in the second direction with the second via is greater than an amount of overlap of the second power supply line on the second side in the second direction with the second via.

10. The semiconductor integrated circuit device of claim 8, wherein
the plurality of standard cells further include a second standard cell disposed adjacent to the second side of the first standard cell,
the second standard cell includes:
a third active region forming a channel, a source, and a drain of a third transistor of the first conductivity type and having a third nanosheet extending in the first direction as the channel; and
a third gate line extending in the second direction and surrounding an outer periphery of the third nanosheet in the second direction and the third direction,
a surface of the third nanosheet on the second side is exposed from the third gate line, and
a distance in the second direction between the first active region and the third active region is greater than a distance in the second direction between the first active region and the second active region.

11. The semiconductor integrated circuit device of claim 8, wherein
the first via has a longer length in the second direction than a length in the first direction.

12. The semiconductor integrated circuit device of claim 8, wherein
the first active region includes a fourth nanosheet forming a channel, a source, and a drain of a fourth transistor of the first conductivity type and extending in the first direction as the channel,
the second active region includes a fifth nanosheet forming a channel, a source, and a drain of a fifth transistor of the second conductivity type and extending in the first direction as the channel,
the first standard cell further includes:
a fourth gate line extending in the second direction and surrounding an outer periphery of the fourth nanosheet in the second direction and the third direction; and
a fifth gate line extending in the second direction and surrounding an outer periphery of the fifth nanosheet in the second direction and the third direction,
the first power supply line is formed on a back surface side of the fourth transistor,
the second power supply line is formed on a back surface side of the fifth transistor,
the fifth nanosheet is disposed on the first side of the fourth nanosheet,
a surface of the fourth nanosheet on the first side is exposed from the fourth gate line, and
a surface of the fifth nanosheet on the second side is exposed from the fifth gate line.

13. The semiconductor integrated circuit device of claim 8, wherein
the plurality of standard cells include a third standard cell disposed side by side with the first standard cell in the first direction,
the third standard cell includes:
a fourth active region forming a channel, a source, and a drain of a sixth transistor of the first conductivity type and having a sixth nanosheet extending in the first direction as the channel;
a fifth active region forming a channel, a source, and a drain of a seventh transistor of the second conductivity type and having a seventh nanosheet extending in the first direction as the channel;
a sixth gate line extending in the second direction and surrounding an outer periphery of the sixth nanosheet in the second direction and the third direction; and
a seventh gate line extending in the second direction and surrounding an outer periphery of the seventh nanosheet in the second direction and the third direction,
the seventh nanosheet is disposed on the first side of the sixth nanosheet,
a surface of the sixth nanosheet on the first side is exposed from the sixth gate line,
a surface of the seventh nanosheet on the second side is exposed from the seventh gate line,
in plan view, a width of the sixth nanosheet in the second direction is greater than a width of the first nanosheet in the second direction, and
in plan view, an end portion of the first nanosheet on the first side and an end portion of the sixth nanosheet on the first side are disposed at the same position in the second direction.

14. A semiconductor integrated circuit device including: a plurality of standard cells including a first standard cell,
the first standard cell including:
a first active region forming a channel, a source, and a drain of a first transistor of a first conductivity type and having a first nanosheet extending in a first direction as the channel;
a second active region forming a channel, a source, and a drain of a second transistor of a second conductivity type which is a conductivity type different from the first conductivity type and having a second nanosheet extending in the first direction as the channel;
a first gate line extending in a second direction perpendicular to the first direction and surrounding an outer periphery of the first nanosheet in the second direction and a third direction perpendicular to the first direction and the second direction;
a second gate line extending in the second direction and surrounding an outer periphery of the second nanosheet in the second direction and the third direction;
a first power supply line formed on a back surface side of the first transistor and extending in the first direction;
a second power supply line formed on a back surface side of the second transistor and extending in the first direction; and
a first via formed in an overlap region between a region of the first active region serving as the source of the first transistor and the first power supply line, the first via connecting the source in the first active region and the first power supply line,
the second nanosheet being disposed on a first side of the first nanosheet, which is one side in the second direction,
a surface of the first nanosheet on a second side which is the other side in the second direction is exposed from the first gate line,
a surface of the second nanosheet on the first side is exposed from the second gate line,
the first via being disposed at a center portion of the first active region in the second direction in plan view.

15. The semiconductor integrated circuit device of claim 14, wherein
the first standard cell further includes:
a second via formed in an overlap region between a region of the second active region serving as the source of the second transistor and the second power supply line, the second via connecting the source in the second active region and the second power supply line, and
the second via is disposed at a center portion of the second active region in the second direction in plan view.

16. The semiconductor integrated circuit device of claim 14, wherein
the plurality of standard cells include a second standard cell disposed adjacent to the second side of the first standard cell,
the second standard cell includes:
a third active region forming a channel, a source, and a drain of a third transistor of the first conductivity type and having a third nanosheet extending in the first direction as the channel; and
a third gate line extending in the second direction and surrounding an outer periphery of the third nanosheet in the second direction and the third direction,
a surface of the third nanosheet on the first side is exposed from the third gate line, and
a distance in the second direction between the first active region and the third active region is smaller than a distance in the second direction between the first active region and the second active region.

17. The semiconductor integrated circuit device of claim 14, wherein
the first via has a longer length in the second direction than a length in the first direction.

18. The semiconductor integrated circuit device of claim 14, wherein
the first active region includes a fourth nanosheet forming a channel, a source, and a drain of a fourth transistor of the first conductivity type and extending in the first direction as the channel,
the second active region includes a fifth nanosheet forming a channel, a source, and a drain of a fifth transistor of the second conductivity type and extending in the first direction as the channel,
the first standard cell further includes:
a fourth gate line extending in the second direction and surrounding an outer periphery of the fourth nanosheet in the second direction and the third direction; and
a fifth gate line extending in the second direction and surrounding an outer periphery of the fifth nanosheet in the second direction and the third direction,
the first power supply line is formed on a back surface side of the fourth transistor,
the second power supply line is formed on a back surface side of the fifth transistor,
the fifth nanosheet is disposed on the first side of the fourth nanosheet,
a surface of the fourth nanosheet on the second side is exposed from the fourth gate line, and
a surface of the fifth nanosheet on the first side is exposed from the fifth gate line.

19. The semiconductor integrated circuit device of claim 14, wherein
the plurality of standard cells include a third standard cell disposed side by side with the first standard cell in the first direction,
the third standard cell includes:
a fourth active region forming a channel, a source, and a drain of a sixth transistor of the first conductivity type and having a sixth nanosheet extending in the first direction as the channel;
a fifth active region forming a channel, a source, and a drain of a seventh transistor of the second conductivity type and having a seventh nanosheet extending in the first direction as the channel;
a sixth gate line extending in the second direction and surrounding an outer periphery of the sixth nanosheet in the second direction and the third direction; and
a seventh gate line extending in the second direction and surrounding an outer periphery of the seventh nanosheet in the second direction and the third direction,
the seventh nanosheet is disposed on the first side of the sixth nanosheet,
a surface of the sixth nanosheet on the second side is exposed from the sixth gate line,
a surface of the seventh nanosheet on the first side is exposed from the seventh gate line,
in plan view, a width of the sixth nanosheet in the second direction is greater than a width of the first nanosheet in the second direction, and
in plan view, an end portion of the first nanosheet on the second side and an end portion of the sixth nanosheet on the second side are disposed at the same position in the second direction.
